(19) United States
(12) Patent Application Publication
(10) Pub. No.: US 2022/0234164 A1
(43) Pub. Date: Jul. 28, 2022

(54) SUBSTRATE PROCESSING SYSTEM

(71) Applicant: Ebara Corporation, Tokyo (JP)

(72) Inventors: Tsuneo TORIKOSHI, Tokyo (JP); Masahiro HATAKEYAMA, Tokyo (JP); Ryo NAKAGOMI, Tokyo (JP)

(73) Assignee: Ebara Corporation, Tokyo (JP)

(21) Appl. No.: 17/612,721

(22) PCT Filed: May 20, 2020
(86) PCT No.: PCT/JP2020/019869

§ 371 Date: Nov. 19, 2021

(30) Foreign Application Priority Data
May 22, 2019 (JP) 2019-095619

(51) Int. Cl. B24B 37/013

(52) U.S. Cl. CPC B24B 37/013

(57) ABSTRACT

It is possible to save labor, energy, and/or cost for a substrate processing apparatus.

It is provided with a sensor installed in a substrate processing apparatus and configured to detect a target physical quantity during processing of a target substrate; and a prediction unit configured to output a polishing end point timing, which is timing of ending polishing, by inputting, to a learned machine learning model, time-series data of the physical quantity detected by the sensor or time-series data obtained by differentiating the time-series data of the physical quantity with respect to time, in which the machine learning model is obtained by machine learning using, as a learning data set, past time-series data of the physical quantity or time-series data obtained by differentiating the past time-series data of the physical quantity with respect to time as input and using the past polishing end point timing as output.

### TECHNICAL FIELD

The present invention relates to a substrate processing system.

### BACKGROUND ART

Various substrate processing apparatuses are used for manufacturing a semiconductor device, and a polishing apparatus represented by a CMP apparatus is used as one of the substrate processing apparatuses. A wiring structure of a semiconductor device is formed by forming a metal film (such as a copper film) on an insulating film in which a groove along a wiring pattern is formed, and then removing an unnecessary metal film by a polishing apparatus. The polishing apparatus polishes a surface of a substrate by relatively moving the substrate and a polishing pad while supplying a polishing liquid (slurry) to the polishing pad on a polishing table.

The conventional polishing apparatus includes a polishing end point detection device that detects a polishing end point of the substrate. The polishing end point detection device monitors the polishing of the substrate based on a polishing index value (for example, a table torque current, an output signal of an eddy current film thickness sensor, and an output signal of an optical film thickness sensor) indicating a film thickness, and determines a time point at which the metal film is removed as the polishing end point.

Hitherto, a service person visits a substrate processing apparatus (for example, a polishing apparatus) to acquire, analyze, and deal with an abnormality of operation data of the substrate processing apparatus. In this case, for example, communication with a design or development department is performed by telephone or e-mail.

For example, in order to remotely monitor and remotely operate a plurality of polishing end point detection devices, Patent Literature 1 discloses that a plurality of polishing end point detection devices and a host computer connected to the plurality of polishing end point detection devices via a network are provided. Patent Literature 1 discloses that the host computer includes a memory that stores polishing end point detection data sent from the plurality of polishing end point detection devices and a display screen that displays the polishing end point detection data, and the host computer sends a new polishing end point detection recipe to at least one polishing end point detection device selected from the plurality of polishing end point detection devices and rewrites the polishing end point detection recipe of the selected at least one polishing end point detection device.

### CITATION LIST

### Patent Literature

Patent Literature 1: JP 2013-176828 A

### SUMMARY OF INVENTION

### Technical Problem

However, since it still takes manpower to rewrite the polishing end point detection recipe, there is a demand for saving labor and automating an apparatus, a unit (operation of the unit or the like), and a factory. In addition, there is a demand for reducing downtime of the substrate processing apparatus, reducing the time and cost for moving relevant personnel, performing analysis, creating a countermeasure against an abnormality, and the like, saving labor, energy, and/or cost, and automating the apparatus, the unit (operation of the unit or the like), and/or a factory.

The present invention has been made in view of the above problems, and an object of the present invention is to provide a substrate processing system capable of saving labor, energy, and/or cost for a substrate processing apparatus.

### Solution to Problem

A substrate processing system according to a first aspect of the present invention includes: a sensor installed in a substrate processing apparatus and configured to detect a target physical quantity during processing of a target substrate; and a prediction unit configured to output a polishing end point timing, which is timing of ending polishing, by inputting, to a learned machine learning model, time-series data of the physical quantity detected by the sensor or time-series data obtained by differentiating the time-series data of the physical quantity with respect to time, in which the machine learning model is obtained by machine learning using, as learning data, past time-series data of the physical quantity or time-series data obtained by differentiating the past time-series data of the physical quantity with respect to time as input and the past polishing end point timing as output.

According to this configuration, since the polishing end point timing can be automatically predicted, it is possible to reduce the time and cost required for predicting the polishing end point timing, and save labor, energy, and/or cost. In addition, conventionally, when time-series data obtained by differentiating time-series data of a current value of a table rotating motor with respect to time is used, a plurality of minimum points or maximum points is generated, and there is a problem that it is not possible to determine which minimum point or maximum point is a polishing end point timing in real time. On the other hand, since the machine learning model after learning is learned using the learning data in which the past time-series data of the physical quantity or the time-series data obtained by differentiating the past time-series data of the physical quantity with respect to time is used as input and the past polishing end point timing is used as output, it is possible to improve the possibility that the correct polishing end point timing can be output even when time-series data of an unknown physical quantity or time-series data obtained by differentiating the time-series data of the physical quantity with respect to time is input.

A substrate processing system according to a second aspect of the present invention is the substrate processing system according to the first aspect, and further includes: a decision unit configured to compare the time-series data of the physical quantity detected by the sensor with the past time-series data and judge whether an abnormality is present in a time-series change in the physical quantity; a determination unit configured to determine a processing condition again when the decision unit judges that the abnormality is present; and an update control unit configured to perform control to perform an update with the processing condition determined by the determination unit.

According to this configuration, since the polishing end point timing can be automatically predicted, the time and cost required for predicting the polishing end point timing are reduced, and when an abnormality is present in a time-series change in the physical quantity, the polishing end point timing is automatically corrected by updating the processing condition (recipe). Therefore, since it is not necessary to go to the site to update the recipe, labor, energy, and/or cost can be saved. Even if site work occurs, the contents of the work can be lighter than before. Specifically, the polishing end point timing can be determined with high accuracy from a change in a waveform, whether the polishing is normally performed can be determined from a time-series change in the physical quantity, and the recipe can be automatically updated even when the polishing is not normally performed.

A substrate processing system according to a third aspect of the present invention is the substrate processing system according to the first or second aspect, in which the target physical quantity is a current value of a table rotating motor of the substrate processing apparatus, a current value of a top ring rotating motor of the substrate processing apparatus, or torque of a table of the substrate processing apparatus, and the substrate processing system further includes: a selection unit configured to select time-series data of a current value detected by the sensor based on time-series data obtained by differentiating the time-series data of the current value with respect to time; and a learning unit configured to generate the learned machine learning model by performing machine learning using, as the learning data set, the time-series data of the current value selected by the selection unit as input and the polishing end point timing as output.

According to this configuration, since it is possible to select only data in which a desired minimum point or maximum point appears in time-series data obtained by differentiating time-series data of a current value with respect to time in the learning data set, it is possible to improve the accuracy of predicting the polishing end point timing.

A substrate processing system according to a fourth aspect of the present invention is the substrate processing system according to the third aspect, in which when a minimum point or a maximum point that satisfies a setting criterion is not detected in the time-series data differentiated with respect to time, the selection unit selects the time-series data of the current value by excluding the time-series data of the current value before the differentiation from the learning data set.

According to this configuration, when the minimum point or the maximum point that satisfies the setting criterion is not detected, it is possible to improve the accuracy of predicting the polishing end point timing by excluding the time-series data of the current value before differentiation from the learning data set.

A substrate processing system according to a fifth aspect of the present invention includes: a sensor installed in a substrate processing apparatus and configured to detect a target physical quantity during processing of a target substrate; storage in which at least one piece of past time-series data of the physical quantity during the processing of the substrate is stored in association with a lot of the substrate; an extraction unit configured to refer to the storage and extract the past time-series data of the physical quantity that corresponds to the lot of the target substrate to be processed; and a decision unit configured to compare the time-series data of the physical quantity detected by the sensor with the past time-series data extracted by the extraction unit and judge whether an abnormality is present in the time-series change in the physical quantity.

According to this configuration, since it is possible to automatically detect that an abnormality is present in the time-series data of the physical quantity of the substrate processing apparatus, it is possible to reduce the time and cost for detecting the abnormality and to save labor, energy, and/or cost.

A substrate processing system according to a sixth aspect of the present invention is the substrate processing system according to the fifth aspect, and further includes: a determination unit configured to determine a processing condition again when the decision unit judges that the abnormality is present; and an update control unit configured to perform control to perform an update with the processing condition determined by the determination unit.

According to this configuration, when an abnormality is present in the time-series data of the physical quantity of the substrate processing apparatus, it is possible to update the processing condition (recipe), and thus, it is possible to reduce the time and cost for creating a countermeasure against the abnormality, and save labor, energy, and/or cost.

A substrate processing system according to a seventh aspect of the present invention includes: at least one sensor installed in a substrate processing apparatus and configured to detect a target physical quantity during processing of a target substrate; first storage in which at least one piece of past time-series data of the physical quantity during the processing of the substrate is stored in association with a lot of the substrate; an extraction unit configured to refer to the first storage and extract the past time-series data of the physical quantity that corresponds to the lot of the target substrate to be processed; a maintenance necessity decision unit configured to compare the time-series data of the physical quantity detected by the sensor at the time of occurrence of an abnormality with the past time-series data of the physical quantity extracted by the extraction unit to judge whether maintenance needs to be performed; second storage in which a combination of presence or absence of an abnormality in at least one or more physical quantities and a factor of the abnormality and/or a solution to the abnormality are stored in association with each other; and a factor analysis unit configured to refer to the second storage and output the factor of the abnormality and/or the solution to the abnormality according to the combination of presence or absence of the abnormality in the one or more physical quantities when the maintenance necessity decision unit judges that the maintenance needs to be performed.

According to this configuration, since maintenance personnel of the substrate processing apparatus can immediately grasp the factor of the abnormality and/or the solution to the abnormality, an abnormality of a polishing apparatus can be quickly resolved, for example, by going to the local polishing apparatus. In addition, it is possible to reduce the time and cost for detecting the factor of the abnormality and/or creating the solution to the abnormality, thereby saving labor, energy, and/or cost.

A substrate processing system according to an eighth aspect of the present invention includes: an information processing apparatus connected to a plurality of substrate processing apparatuses via a communication line; and a fog computer or a terminal connected to the information processing apparatus via a communication line. The information processing apparatus collects data from the plurality of substrate processing apparatuses, processes the collected data, and transmits a result of the processing to the fog computer or the terminal. The fog computer or the terminal performs control to output the result of the processing upon receiving the result of the processing.

According to this configuration, the fog computer or the terminal can output a result of processing data collected by the information processing apparatus from the plurality of substrate processing apparatuses.

A substrate processing system according to a ninth aspect of the present invention is the substrate processing system according to the eighth aspect, in which the information processing apparatus includes: means for extracting, from the collected data, parameters having a correlation of a standard or higher with a substrate processing condition, a substrate processing table state, and/or dressing uniformity; and means for comparing the extracted parameters between the substrate processing apparatuses and updating at least one parameter of the data according to a result of the comparison.

According to this configuration, since substrate processing conditions (for example, polishing conditions), substrate processing table states (for example, polishing table states), and/or dressing uniformity can be brought close to each other, it is possible to reduce a variation in the substrate processing (for example, polishing) between the substrate processing apparatuses (for example, polishing apparatuses).

### Advantageous Effects of Invention

According to one aspect of the present invention, since the polishing end point timing can be automatically predicted, the time and cost required for predicting the polishing end point timing are reduced, and the recipe can be automatically updated when an abnormality is present in polishing, so that labor, energy, and/or cost can be saved. In addition, conventionally, when time-series data obtained by differentiating time-series data of a current value of a table rotating motor with respect to time is used, a plurality of minimum points or maximum points is generated, and there is a problem that it is not possible to determine which minimum point or maximum point is a polishing end point timing in real time. This problem has an aspect that it is difficult to detect the waveform of the time-series data due to the shape and an aspect that it is difficult to detect the waveform of the time-series data due to noise. On the other hand, AI such as machine learning can solve this problem by being applied to waveform analysis, noise removal, and tendency analysis. Specifically, since the machine learning model after learning is learned using the learning data set in which the past time-series data of the physical quantity or the time-series data obtained by differentiating the past time-series data of the physical quantity with respect to time is used as input and the past polishing end point timing is used as output, it is possible to improve the possibility that the correct polishing end point timing can be output even when time-series data of an unknown physical quantity or time-series data obtained by differentiating the time-series data of the physical quantity with respect to time is input. According to another aspect of the present invention, since it is possible to automatically detect that an abnormality is present in the time-series data of the physical quantity of the substrate processing apparatus, it is possible to reduce the time and cost for detecting the abnormality, and save labor, energy, and/or cost. According to another aspect of the present invention, since the maintenance personnel of the substrate processing apparatus can immediately grasp the factor of the abnormality and/or the solution to the abnormality, the abnormality of the polishing apparatus can be quickly resolved, for example, by going to the local polishing apparatus. In addition, it is possible to reduce the time and cost for detecting the factor of the abnormality and/or creating the solution to the abnormality, thereby saving labor, energy, and/or cost.

### BRIEF DESCRIPTION OF DRAWINGS

FIG. 1 is a diagram illustrating a schematic configuration of a substrate processing system according to a first embodiment.

FIG. 2 is a schematic diagram illustrating a polishing apparatus according to the first embodiment.

FIG. 3 is a diagram illustrating a schematic configuration of a recipe server according to the first embodiment.

FIG. 4 is an example of a table stored in storage of the recipe server.

FIG. 5 is a diagram illustrating a schematic configuration of an alarm server according to the first embodiment.

FIG. 6 is a diagram illustrating a schematic configuration of an analysis server according to the first embodiment.

FIG. 7 illustrates an example of a table stored in storage of the analysis server.

FIG. 8 is a diagram illustrating a schematic configuration of a predictive maintenance server according to the first embodiment.

FIG. 9 is a schematic diagram illustrating an example of waveforms of a motor current and a differential value of the motor current.

FIG. 10 is a schematic diagram illustrating another example of the waveforms of the motor current and the differential value of the motor current.

FIG. 11 is a schematic diagram for explaining a process of generating a polishing end point timing according to the present embodiment.

FIG. 12 is a schematic diagram for explaining a process of updating a processing condition (recipe) according to the present embodiment.

FIG. 13 is a schematic diagram for explaining a process of deciding whether maintenance needs to be performed according to the present embodiment.

FIG. 14 is a diagram for explaining a comparison process in a maintenance necessity decision unit 663.

FIG. 15 is a diagram illustrating a schematic configuration of a substrate processing system according to a second embodiment.

FIG. 16 is a diagram illustrating a schematic configuration of a substrate processing system according to a third embodiment.

FIG. 17 is a table summarizing functions and mechanisms in each operation unit in the substrate processing systems according to the first to third embodiment.

FIG. 18 is an example of a neural network according to each embodiment.

FIG. 19 is a diagram illustrating a schematic configuration of a substrate processing system according to a fourth embodiment.

### DESCRIPTION OF EMBODIMENTS

Hereinafter, each embodiment will be described with reference to the drawings. However, unnecessarily detailed description may be omitted. For example, a detailed description of a well-known matter and a repeated description of substantially the same configuration may be omitted. This is to avoid unnecessary redundancy of the following description and to facilitate understanding of those skilled in the art.

In the present embodiment, a polishing apparatus will be described as an example of a substrate processing apparatus. In addition, the polishing apparatus according to the present embodiment includes a polishing end point detection device that detects a polishing end point of a substrate. The polishing end point detection device monitors polishing of the substrate based on a polishing index value (for example, an output signal indicating torque, such as a current value of a table rotating motor, torque of a table, or a current value of a top ring rotating motor, an output signal of an eddy current film thickness sensor, and an output signal of an optical film thickness sensor) indicating a film thickness, and determines, as the polishing end point, a time point at which a metal film is removed. In the present embodiment, as an example, the description will be given assuming that the current value of the table rotating motor is used as the polishing index value indicating the film thickness.

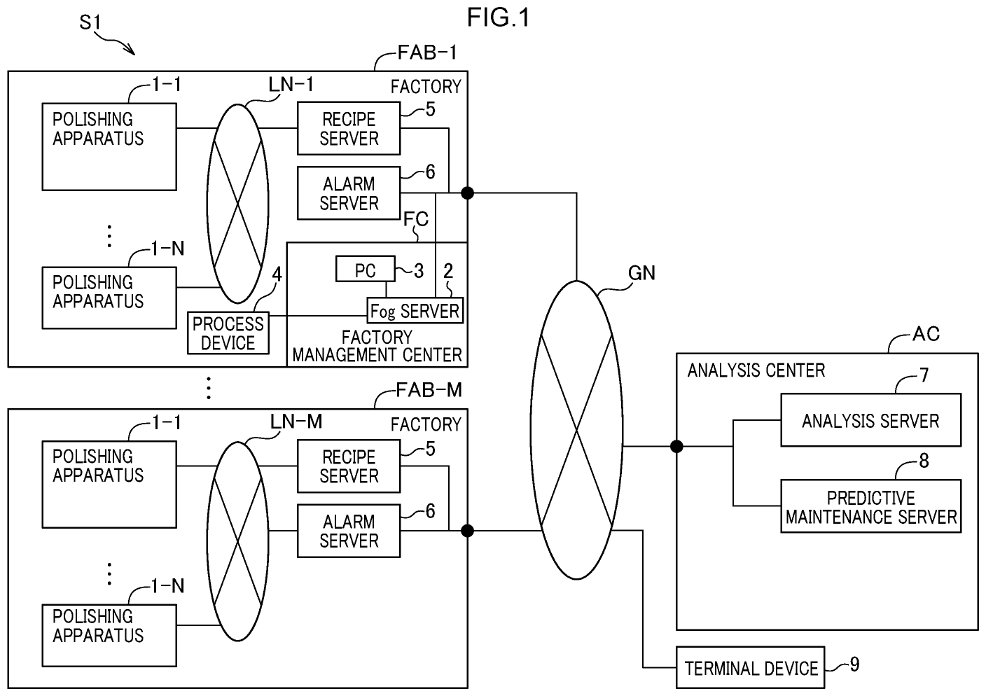

FIG. 1 is a diagram illustrating a schematic configuration of a substrate processing system according to a first embodiment. As illustrated in FIG. 1, in the substrate processing system S1, polishing apparatuses 1-1 to 1-N (N is a positive integer) are provided for each of factories FAB-1 to FAB-M (M is a positive integer). In this case, in order to simplify the description, it is assumed that the number of polishing apparatuses is the same for each factory, but may be different for each factory.

In the substrate processing system S1, a recipe server 5 and an alarm server 6 are provided for each of the factories FAB-1 to FAB-M (M is a positive integer). The polishing apparatuses 1-1 to 1-N, the recipe server 5, and the alarm server 6 are communicably connected to each other by a local area network LN-i (i is an integer from 1 to M).

As an example, the factory FAB-1 is provided with a process device 4. As an example, the factory FAB-1 is provided with a factory management center FC, and the factory management center FC is provided with a Fog server 2 communicably connected to the process device 4 and a personal computer (PC) 3 communicably connected to the Fog server 2. In this case, the Fog server 2 is connected to a global network GN and can communicate with the recipe servers 5, the alarm servers 6, an analysis server 7, and a predictive maintenance server 8 via the global network GN.

Each recipe server 5 is connected to the global network GN and can communicate with the analysis server 7 and the predictive maintenance server 8 that are provided in an analysis center AC. In addition, each alarm server 6 is connected to the global network GN and can communicate with the analysis server 7 and the predictive maintenance server 8 that are provided in the analysis center AC. The substrate processing system S1 includes the analysis server 7 and the predictive maintenance server 8. The analysis server 7 and the predictive maintenance server 8 are connected to the global network GN. Further, the substrate processing system S1 includes a terminal device 9. The terminal device 9 is connected to the global network GN and can communicate with the predictive maintenance server 8. Hereinafter, the polishing apparatuses 1-1 to 1-N are collectively referred to as a polishing apparatus 1.

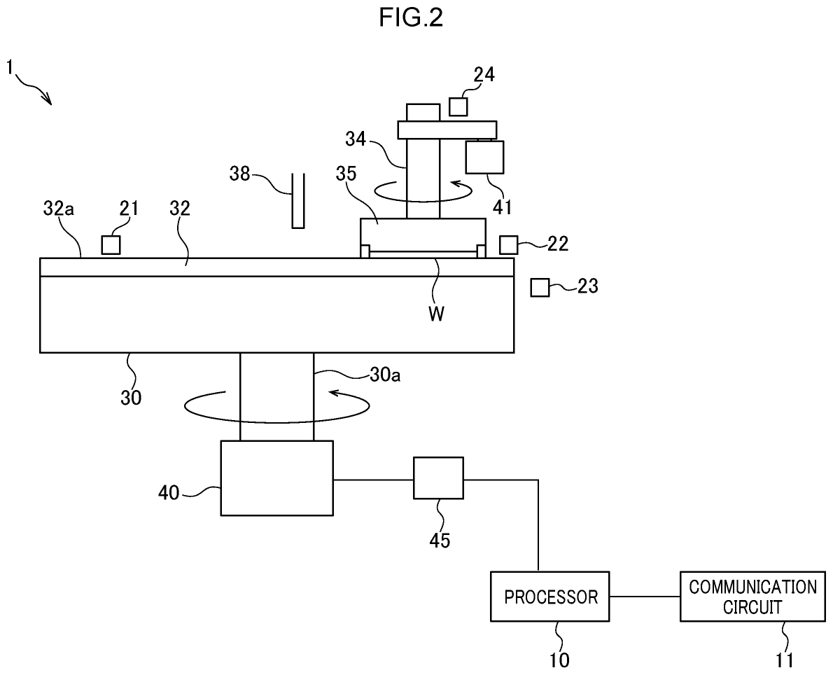

FIG. 2 is a schematic diagram illustrating the polishing apparatus according to the first embodiment. This polishing apparatus is a CMP apparatus that chemically mechanically polishes a substrate. As illustrated in FIG. 2, the polishing apparatus includes a polishing table 30, a top ring 35 connected to a lower end of a top ring shaft 34, and a processor 10 that detects the polishing end point. The top ring shaft 34 is connected to and rotationally driven by the top ring rotating motor 41 via connecting means such as a timing belt. The rotation of the top ring shaft 34 rotates the top ring 35 about the top ring shaft 34 in a direction indicated by an arrow. The substrate (for example, wafer) W to be polished is held on the lower surface of the top ring 35 by vacuum adsorption or adsorption by a membrane.

The polishing table 30 is connected to a table rotating motor 40 disposed under the polishing table 30 via a table shaft 30a, and is rotated by the table rotating motor 40 about the table shaft 30a in a direction indicated by an arrow. A polishing pad 32 is attached to the upper surface of the polishing table 30, and a polishing surface 32a which is the upper surface of the polishing pad 32 polishes the substrate W. A polishing liquid supply mechanism 38 for supplying a polishing liquid (slurry) to the polishing surface 32a is disposed above the polishing table 30.

The substrate W is polished as follows. The top ring 35 and the polishing table 30 are rotated by the top ring rotating motor 41 and the table rotating motor 40, respectively, and the polishing liquid is supplied from the polishing liquid supply mechanism 38 to the polishing surface 32a of the polishing pad 32. In this state, the top ring 35 presses the substrate W against the polishing surface 32a. The substrate W is polished by a mechanical action due to sliding contact with the polishing pad 32 and a chemical action of the polishing liquid.

A table motor current detection unit 45 that detects a motor current is connected to the table rotating motor 40. Furthermore, the table motor current detection unit 45 is connected to the processor 10. During the polishing of the substrate W, since the surface of the substrate W and the polishing surface 32a of the polishing pad 32 come into sliding contact with each other, a frictional force is generated between the substrate W and the polishing pad 32. This frictional force acts on the table rotating motor 40 as resistance torque.

The polishing apparatus 1 includes the processor 10 and further includes a communication circuit 11 connected to the processor 10. The processor 10 outputs time-series data of the motor current (torque current) measured by the table motor current detection unit 45 from the communication circuit 11 to the recipe server 5. The processor 10 acquires a polishing end point timing transmitted from the recipe server 5 via the communication circuit 11 according to the time-series data of the motor current (torque current).

In a substrate having a laminated structure, a plurality of films of different types is formed. When the uppermost film is removed by polishing, a lower film thereunder appears on the surface. Since these films usually have different hardness, when the upper film is removed and the lower film appears, the frictional force between the substrate W and the polishing pad 32 changes. This change in the frictional force can be detected as a change in torque applied to the table rotating motor 40.

A learning unit 762 of the analysis server 7 that is described later generates a learned machine learning model by performing machine learning using, as a learning data set, past time-series data of a physical quantity as input and the past polishing end point timing as output. In this case, an operator or a device having a decision function determines that the film has been removed, based on a change in a current to the table rotating motor 40, that is, the polishing end point timing included in the learning data set provided to the learning unit 762 is determined by the operator or the device having the decision function based on the change in the current to the table rotating motor 40. The processor 10 may monitor a current output from a motor driver (not illustrated) connected to the table rotating motor 40 without providing the table motor current detection unit 45.

The polishing apparatus 1 is provided with, for example, sensors 21 to 24. The sensor 21 detects a flow rate of water or slurry. The sensor 22 detects the polishing pressure. The sensor 23 detects the rotation speed of the polishing table 30. The sensor 24 detects the rotation speed of the top ring 35. These detection signals are output to the processor 10, and the processor 10 transmits these detection signals from the communication circuit 11 to another server.

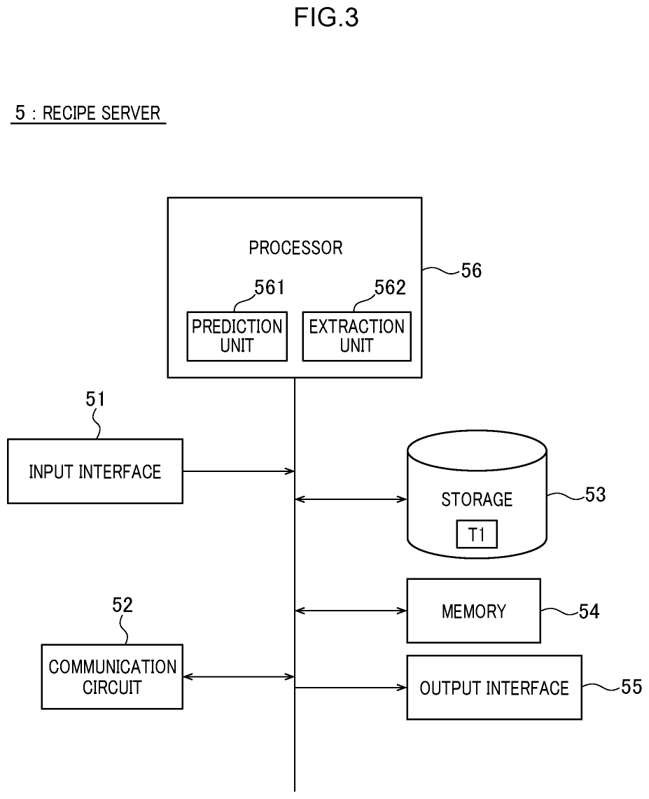

FIG. 3 is a diagram illustrating a schematic configuration of the recipe server according to the first embodiment. As illustrated in FIG. 3, the recipe server 5 includes an input interface 51, a communication circuit 52, storage 53, a memory 54, an output interface 55, and a processor 56.

The input interface 51 is, for example, a keyboard, and receives input from an administrator of the recipe server 5. The communication circuit 52 communicates with the polishing apparatuses 1-1 to 1-N and the alarm server 6 via the connected local area network LN-i (i is an integer from 1 to M). In addition, the communication circuit 52 communicates with the analysis server 7 and the predictive maintenance server 8 via the global network GN. The communication may be wired or wireless communication, but will be described as being wired communication as an example.

The storage 53 stores programs to be read and executed by the processor 56 and various data, and is, for example, a nonvolatile memory (for example, a hard disk drive).

The memory 54 temporarily holds data and programs, and is, for example, a volatile memory (for example, a random access memory (RAM)).

The output interface 55 is an interface connected to an external device.

The processor 56 functions as a prediction unit 561 and an extraction unit 562 by loading a program from the storage 53 into the memory 54 and executing a series of instructions included in the program.

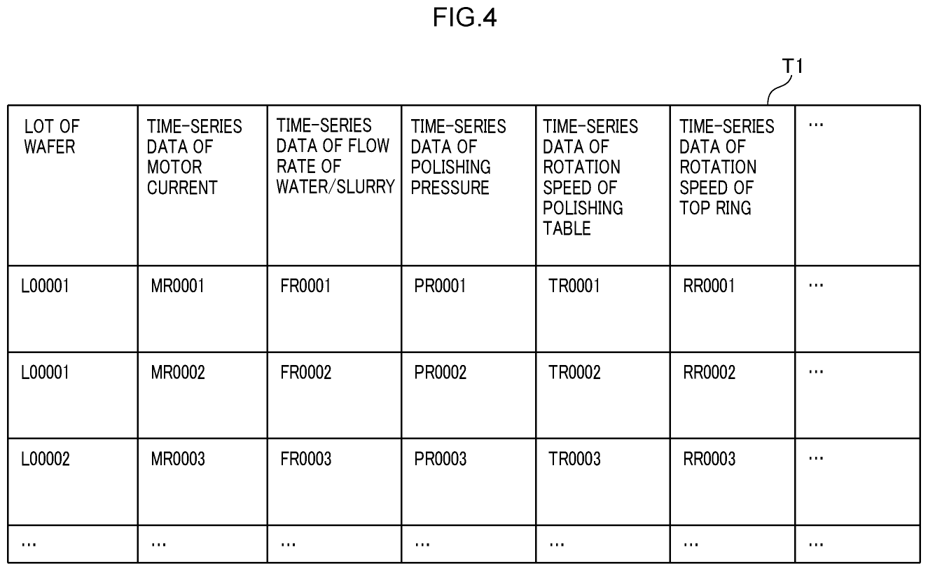

FIG. 4 is an example of a table stored in the storage of the recipe server. As illustrated in FIG. 4, the table T1 stores a record of a set of a lot of a wafer, time-series data of the motor current, time-series data of the flow rate of water or slurry, time-series data of the polishing pressure, time-series data of the rotation speed of the polishing table, time-series data of the rotation speed of the top ring, and the like. As described above, the storage 53 stores at least one piece of past time-series data of the target physical quantity (for example, the motor current, the flow rate of water or slurry, the polishing pressure, the rotation speed of the polishing table) during the processing of the substrate in association with the lot of the substrate.

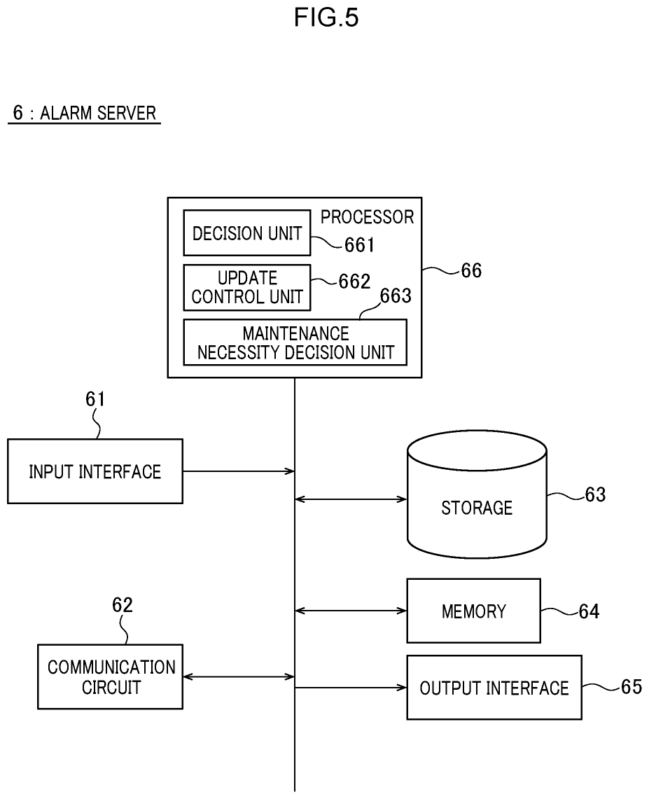

FIG. 5 is a diagram illustrating a schematic configuration of the alarm server according to the first embodiment. As illustrated in FIG. 5, the alarm server 6 includes an input interface 61, a communication circuit 62, storage 63, a memory 64, an output interface 65, and a processor 66.

The input interface 61 is, for example, a keyboard, and receives input from an administrator of the alarm server 6.

The communication circuit 62 communicates with the polishing apparatuses 1-1 to 1-N and the recipe server 5 via the connected local area network LN-i (i is an integer from 1 to M). In addition, the communication circuit 52 communicates with the analysis server 7 and the predictive maintenance server 8 via the global network GN. The communication may be wired or wireless communication, but will be described as being wired communication as an example.

The storage 63 stores programs to be read and executed by the processor 66 and various data, and is, for example, a nonvolatile memory (for example, a hard disk drive).

The memory 64 temporarily holds data and programs, and is, for example, a volatile memory (for example, a random access memory (RAM)).

The output interface 65 is an interface connected to an external device.

The processor 66 functions as a decision unit 661, an update control unit 662, and a maintenance necessity decision unit 663 by loading a program from the storage 63 into the memory 64 and executing a series of instructions included in the program.

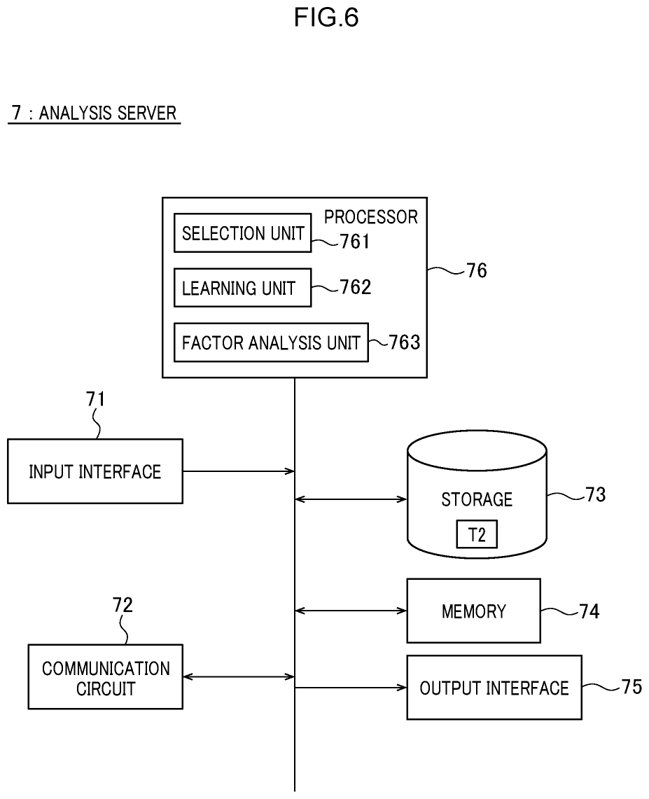

FIG. 6 is a diagram illustrating a schematic configuration of the analysis server according to the first embodiment. As illustrated in FIG. 6, the analysis server 7 includes an input interface 71, a communication circuit 72, storage 73, a memory 74, an output interface 75, and a processor 76.

The input interface 71 is, for example, a keyboard, and receives input from an administrator of the analysis server 7.

The communication circuit 72 communicates with the recipe servers 5, the alarm servers 6, and the predictive maintenance server 8 via the global network GN. The communication may be wired or wireless communication, but will be described as being wired communication as an example.

The storage 73 stores programs to be read and executed by the processor 76 and various data, and is, for example, a nonvolatile memory (for example, a hard disk drive).

The memory 74 temporarily holds data and programs, and is, for example, a volatile memory (for example, a random access memory (RAM)).

The output interface 75 is an interface connected to an external device.

The processor 76 functions as a selection unit 761, a learning unit 762, and a factor analysis unit 763 by loading a program from the storage 73 into the memory 74 and executing a series of instructions included in the program.

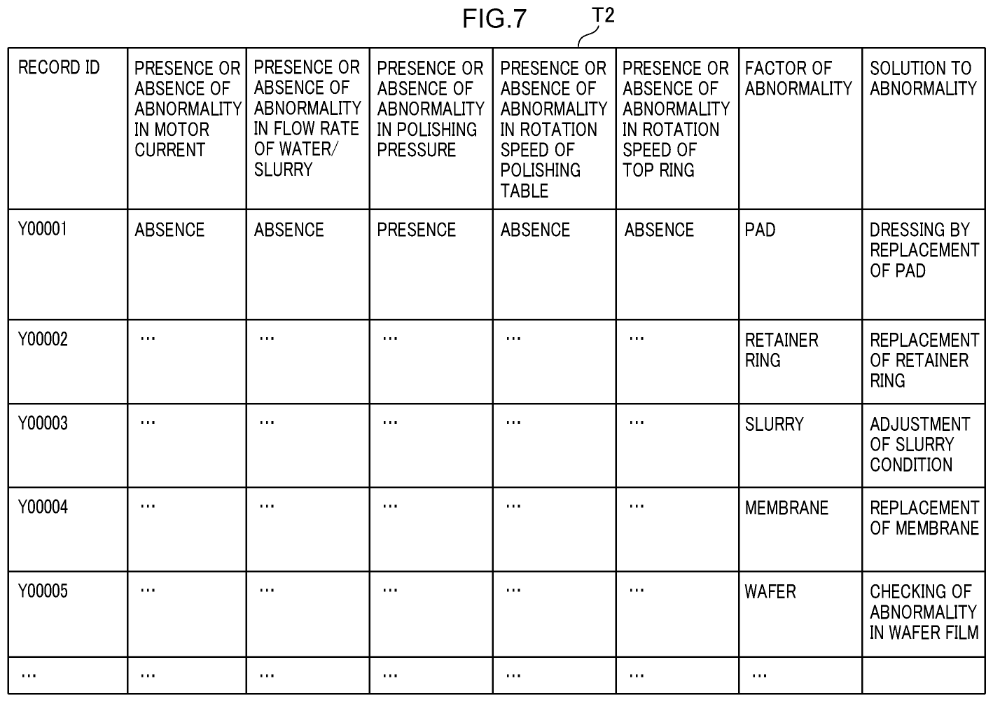

FIG. 7 illustrates an example of a table stored in the storage of the analysis server. As illustrated in FIG. 7, a table T2 stores a record of a set of a record ID which is identification information identifying the record, the presence or absence of an abnormality in the motor current, the presence or absence of an abnormality in the flow rate of water or slurry, the presence or absence of an abnormality in the polishing pressure, the presence or absence of an abnormality in the rotation speed of the polishing table, the presence or absence of an abnormality in the rotation speed of the top ring, a factor of an abnormality, and a solution to the abnormality. As described above, the combination of the presence or absence of an abnormality in at least one or more of the physical quantities and the factor of the abnormality and/or the solution to the abnormality are stored in the storage 83 in association with each other.

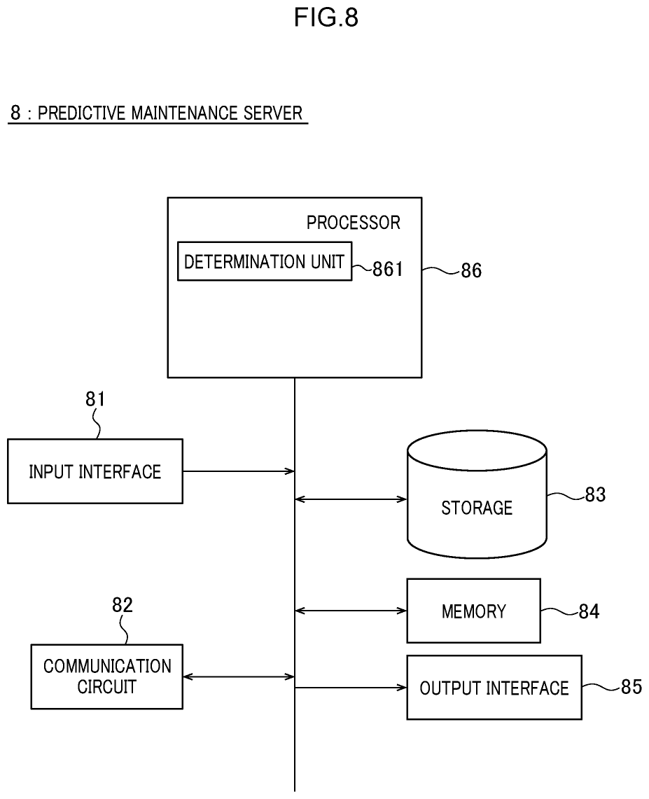

FIG. 8 is a diagram illustrating a schematic configuration of the predictive maintenance server according to the first embodiment. As illustrated in FIG. 8, the predictive maintenance server 8 includes an input interface 81, a communication circuit 82, storage 83, a memory 84, an output interface 85, and a processor 86.

The input interface 81 is, for example, a keyboard, and receives input from an administrator of the predictive maintenance server 8. The communication circuit 82 communicates with the recipe servers 5, the alarm servers 6, and the analysis server 7 via the global network GN. The communication may be wired or wireless communication, but will be described as being wired communication as an example.

The storage 83 stores programs to be read and executed by the processor 86 and various data, and is, for example, a nonvolatile memory (for example, a hard disk drive).

The memory 84 temporarily holds data and programs, and is, for example, a volatile memory (for example, a random access memory (RAM)).

The output interface 85 is an interface connected to an external device.

The processor 86 functions as a determination unit 861 by loading a program from the storage 83 into the memory 84 and executing a series of instructions included in the program.

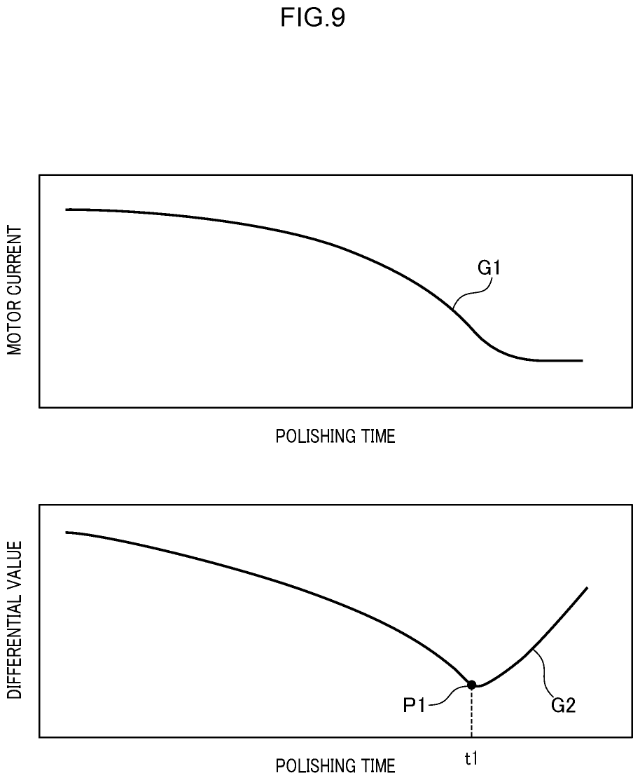

FIG. 9 is a schematic diagram illustrating an example of waveforms of the motor current and a differential value of the motor current. A waveform G1 indicates the relationship between the motor current and the polishing time, and a waveform G2 indicates the relationship between the differential value of the motor current and the polishing time. As indicated by the waveform G2, in a case where a minimum point P1 appears, it can be determined that the end point detection timing is a time t1 at which the minimum point P1 is obtained.

However, when a plurality of minimum points (or maximum points) is present, there is a problem that it is not possible to determine in real time which minimum point (or maximum point) is the end point detection timing. In addition, there is also a problem that normal decision cannot be made when noise is included in the waveform. In the present embodiment, as an example, the learning unit 762 of the analysis server 7 generates a learned machine learning model by performing machine learning using, as the learning data set, past time-series data of the motor current value as input and the polishing end point timing as output, thereby solving the problem.

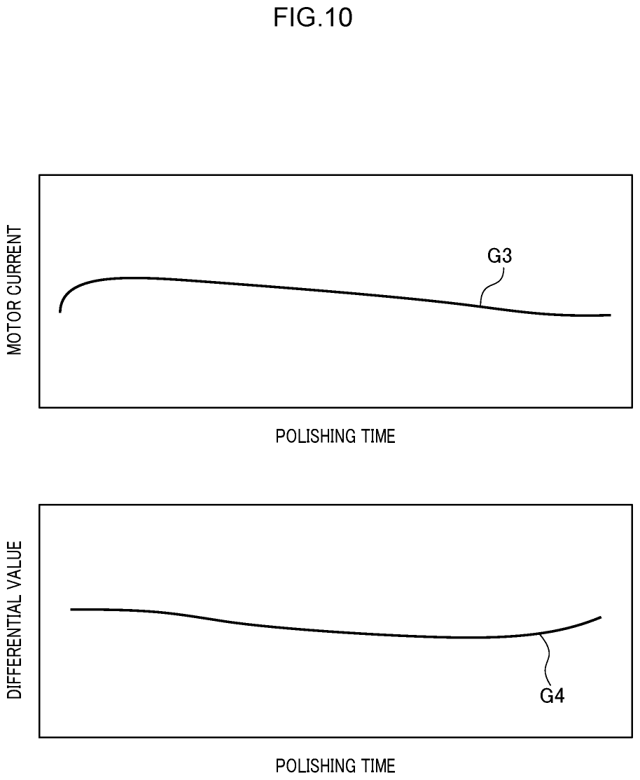

FIG. 10 is a schematic diagram illustrating another example of the waveforms of the motor current and the differential value of the motor current. A waveform G3 indicates the relationship between the motor current and the polishing time, and a waveform G4 indicates the relationship between the differential value of the motor current and the polishing time. In the waveform G4, since the minimum point (or the maximum point) does not appear, a worker cannot determine the end point detection timing. Therefore, it is necessary to remove this data from the learning data set.

Therefore, the selection unit 761 of the analysis server 7 selects time-series data of the current value based on time-series data obtained by differentiating the time-series data of the current value detected by the sensor with respect to time. Specifically, for example, in a case where the minimum point or the maximum point that satisfies a setting criterion is not detected in the time-series data differentiated with respect to the time, the selection unit 761 selects the time-series data of the current value by excluding the time-series data of the current value before the differentiation. According to this, when the minimum point or the maximum point that satisfies the setting criterion is not detected, it is possible to improve the accuracy of predicting the polishing end point timing by excluding the time-series data of the current value before differentiation from the learning data set.

In this case, the setting criterion is, for example, a condition that the differential value of the current value falls below a preset threshold (or is not larger than the threshold). In addition, for example, since it is known that the second-order differential value of the time-series data of the original current value is 0 and the third-order differential value is positive at the minimum point of the time-series data differentiated with respect to time, the setting criterion may be a condition that the second-order differential value of the time-series data of the original current value is within a preset range based on 0 and the third-order differential value of the time-series data of the original current value is positive.

Then, the learning unit 762 of the analysis server 7 generates a learned machine learning model, for example, by performing machine learning using, as the learning data set, the time-series data of the current value selected by the selection unit 761 as input and the polishing end point timing as output. In this case, the machine learning model is, for example, a model obtained by machine learning using, as the learning data set, the time-series data of the current value as input and the polishing end point timing is used as output. When, for example, the time-series data of the current value is input to the learned machine learning model, a candidate value of the polishing end point timing and a correct prediction probability of the candidate value are output from the learned machine learning model.

According to this configuration, since it is possible to select only data in which a desired minimum point (or maximum point) appears in the time-series data obtained by differentiating the time-series data of the current value with respect to time in the learning data set, it is possible to improve the accuracy of predicting the polishing end point timing.

In the present embodiment, as an example, the current value has been described as the current value of the table rotating motor of the polishing apparatus, but the present invention is not limited thereto, and the current value may be the current value of the top ring rotating motor of the polishing apparatus or the torque of the table of the polishing apparatus.

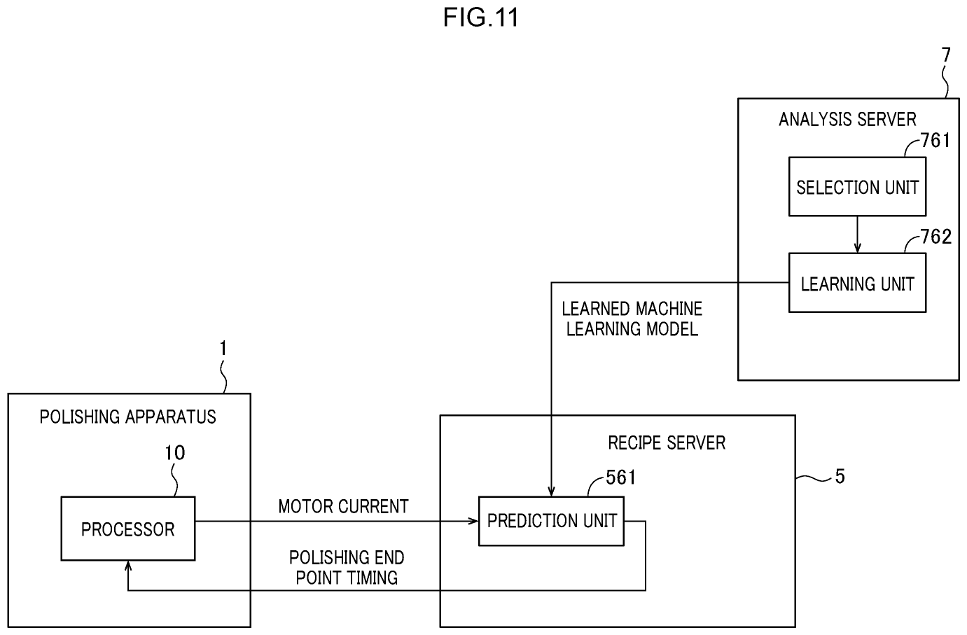

FIG. 11 is a schematic diagram for explaining a process of generating the polishing end point timing according to the present embodiment. As illustrated in FIG. 11, the learning unit 762 of the analysis server 7 transmits the learned machine learning model to the prediction unit 561 of the recipe server 5. As a result, the learning unit 762 of the analysis server can update the learned machine learning model used by the prediction unit 561 at any time.

After receiving the learned machine learning model from the learning unit 762, the prediction unit 561 of the recipe server 5 stores the learned machine learning model to the storage 53. Every time the current value (motor current) of the table rotating motor is acquired, the processor 10 of the polishing apparatus 1 outputs the data to the prediction unit 561. Every time the current value (motor current) of the table rotating motor is received from the polishing apparatus 1, the prediction unit 561 of the recipe server 5 receives the machine learning model that has learned time-series data of the current value (motor current) of the table rotating motor that has been received from the start of the polishing to that time, and outputs a correct prediction probability for each candidate value of the polishing end point timing. As a result, the prediction unit 561 outputs the correct prediction probability for each candidate value of the polishing end point timing from the time-series data of the motor current up to that time with respect to the motor current that changes from moment to moment. When the correct prediction probability of the candidate value exceeds a threshold probability (for example, 90%), the prediction unit 561 sets the predicted value of the polishing end point timing as the polishing end point timing to be output.

As described above, the prediction unit 561 inputs the time-series data of the physical quantity (in this case, the current value of the table rotating motor as an example) detected by the sensor (in this case, the table motor current detection unit 45 as an example) to the learned machine learning model, thereby outputting the polishing end point timing which is the timing of ending the polishing. As a result, since learning is performed using the time-series data of the current value of the table rotating motor when a plurality of minimum points (or maximum points) appeared in the past and the correct polishing end point timing at that time, even when a plurality of minimum points (or maximum points) appear in the time-series waveform of the differential value of the current value of the table rotating motor, it is possible to predict which minimum point (or maximum point) timing is the correct polishing end point timing.

The prediction unit 561 of the recipe server 5 performs control to transmit the polishing end point timing to be output to the polishing apparatus 1. As a result, the processor 10 of the polishing apparatus 1 can acquire the polishing end point timing.

Although a description will be given assuming that the past time-series data of the motor current value is used as the input of the learning data set, the present invention is not limited thereto, and past time-series data of the differential value of the motor current value may be used. In this case, based on time-series data obtained by differentiating the time-series data of the physical quantity (in this case, the current value of the table rotating motor as an example) detected by the sensor with respect to time, the selection unit 761 may select the time-series data differentiated with respect to the time. Then, the learning unit 762 may generate a learned machine learning model by performing machine learning using, as the learning data set, “time-series data obtained by differentiating the time-series data of the physical quantity (in this case, the current value of the table rotating motor as an example) with respect to time” selected by the selection unit 761 as input and the polishing end point timing as output.

In this case, the machine learning model is obtained by machine learning using, as the learning data set, the time-series data obtained by differentiating the time-series data of the physical quantity (in this case, the current value of the table rotating motor as an example) with respect to time as input and using the polishing end point timing as output. In this case, the prediction unit 561 inputs the time-series data obtained by differentiating the time-series data of the physical quantity (in this case, the current value of the table rotating motor as an example) detected by the sensor (in this case, the table motor current detection unit 45 as an example) with respect to time to the learned machine learning model, thereby outputting the polishing end point timing which is the timing of ending the polishing.

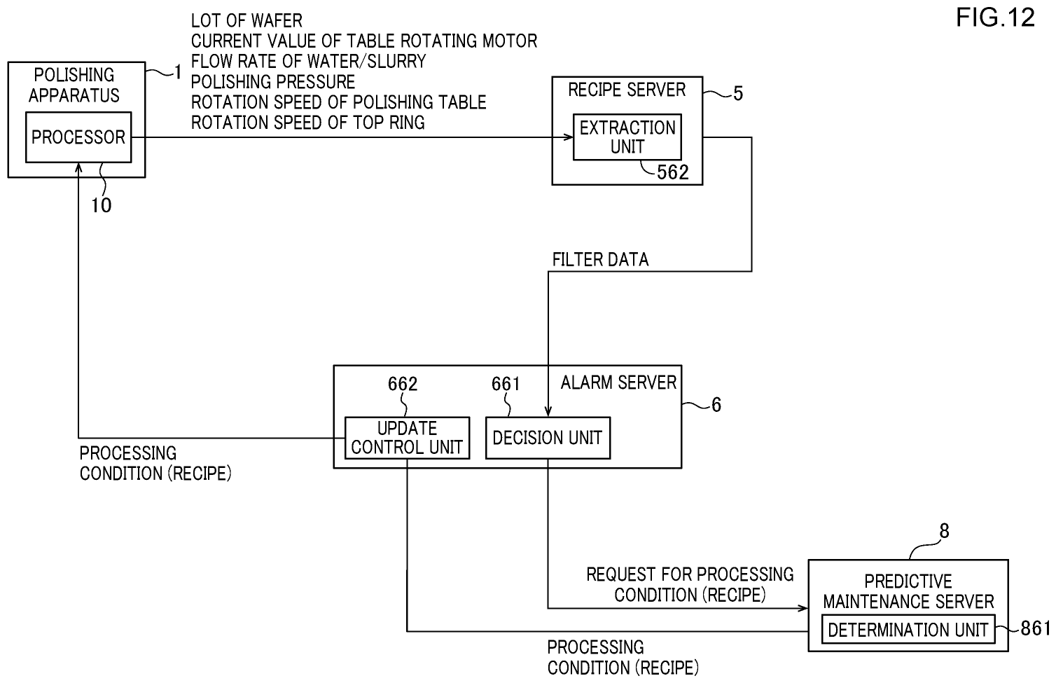

FIG. 12 is a schematic diagram for explaining a process of updating a processing condition (recipe) according to the present embodiment. The processor 10 of the polishing apparatus 1 outputs the lot of the wafer and a second physical quantity such as the flow rate of water/or slurry, the polishing pressure, the rotation speed of the polishing table, or the rotation speed of the top ring to the recipe server 5. In this case, the second physical quantity is a physical quantity during the processing of the target substrate, and is detected by a second sensor (in this case, the sensors 21 to 24 as an example) installed in the substrate processing apparatus (in this case, the polishing apparatus 1 as an example).

The extraction unit 562 of the recipe server 5 refers to the storage 53 and extracts past time-series data of the physical quantity (for example, at least one of the current value of the table rotating motor, the flow rate of water/or slurry, the polishing pressure, the rotation speed of the polishing table, and/or the rotation speed of the top ring, and the like) that corresponds to the lot (in this case, the lot of the wafer received from the processor 10 as an example) of the target substrate to be processed. In this case, the storage 53 stores the lot of the substrate and the past time-series data of the physical quantity (for example, at least one of the current value of the table rotating motor, the flow rate of water/or slurry, the polishing pressure, the rotation speed of the polishing table, and/or the rotation speed of the top ring, and the like) during the processing of the substrate in association with each other. In this case, for example, the extraction unit 562 may extract one or a plurality of pieces of the past time-series data that correspond to the lot of the target substrate to be processed in the storage 53, or may extract a statistical value such as an average value of the time-series data or a median value of the time-series data.

Then, the extraction unit 562 controls the communication circuit 52 to transmit the extracted time-series data to the alarm server 6 as one of data pieces included in filter data.

The decision unit 661 of the alarm server 6 compares the time-series data of the physical quantity (for example, at least one of the current value of the table rotating motor, the flow rate of water/or slurry, the polishing pressure, the rotation speed of the polishing table, and/or the rotation speed of the top ring, and the like) detected by the sensor (in this case, the table motor current detection unit 45 or the sensors 21 to 24 as an example) with the past time-series data extracted by the extraction unit 562, and judges whether an abnormality is present in a time-series change in the physical quantity. According to this configuration, since it is possible to automatically detect that an abnormality is present in the time-series data of the physical quantity of the polishing apparatus 1, it is possible to reduce the time and cost for detecting the abnormality and to save labor, energy, and/or cost.

For example, when the time-series data of the physical quantity detected by the table motor current detection unit 45 this time is out of a range set based on the time-series data extracted by the extraction unit 562, the decision unit 661 judges that an abnormality is present. On the other hand, when the time-series data is within the range set based on the time-series data extracted by the extraction unit 562, the decision unit 661 judges that an abnormality is not present. When the decision unit 661 judges that an abnormality is present, the decision unit 661 requests the predictive maintenance server 8 to provide the processing condition (recipe) in order to update the processing condition (recipe) of the polishing apparatus.

In response to this, the determination unit 861 of the predictive maintenance server 8 determines the processing condition (recipe) again when the decision unit 661 judges that an abnormality is present. The determination unit 861 controls the communication circuit 82 to transmit the redetermined processing condition (recipe) to the alarm server 6. The update control unit 662 that has acquired the redetermined processing condition (recipe) performs control to perform an update with the processing condition determined by the determination unit 861. In this case, the update control unit 662 controls the communication circuit 62 to transmit this processing condition to the polishing apparatus 1. In this manner, an abnormality is automatically judged, (1) the recipe is automatically updated, (2) a result of updating the recipe is reported after the update of the recipe, and (3) an alert is notified when the abnormality is still present even though the recipe is updated. As a result, while a person in charge of maintenance moves quickly, labor can be saved by an automatic movement of a part that moves automatically.

According to this configuration, when an abnormality is present in the time-series data of the physical quantity of the polishing apparatus 1, the processing condition (recipe) can be updated, so that it is possible to reduce the time and cost for creating a countermeasure against the abnormality, and save labor, energy, and/or cost.

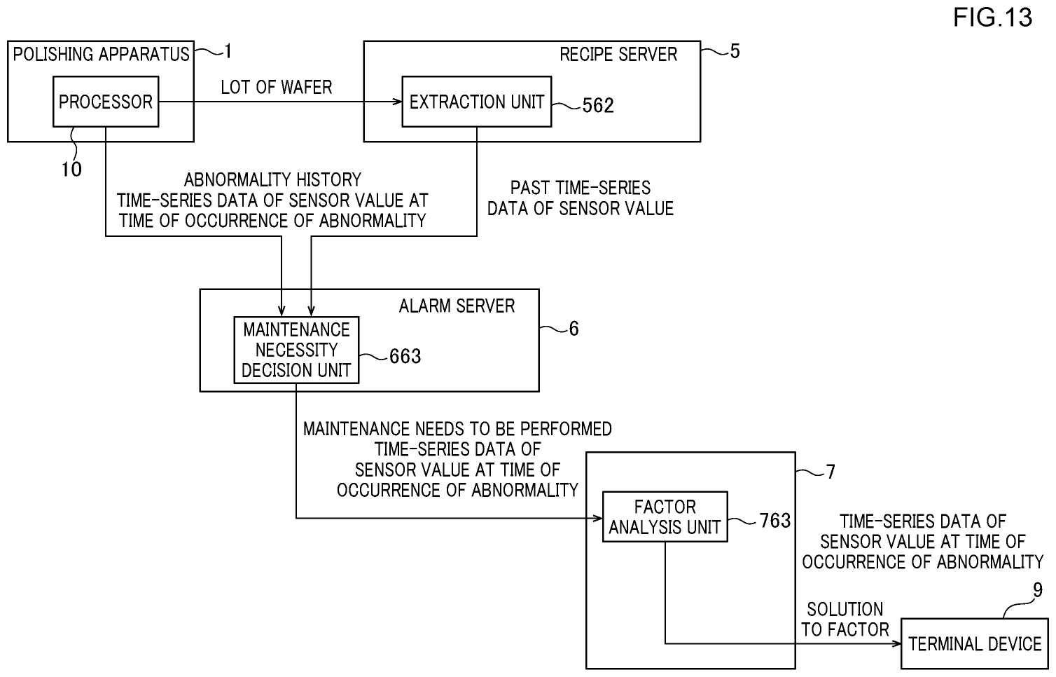

FIG. 13 is a schematic diagram for explaining a process of deciding whether maintenance needs to be performed according to the present embodiment. As illustrated in FIG. 13, the processor 10 controls the communication circuit 11 to transmit an abnormality history and a related data set including the time-series data of the target physical quantity at the time of the occurrence of the abnormality detected by the sensor (in this case, the table motor current detection unit 45 and/or the sensors 21 to 24 as an example) to the maintenance necessity decision unit 663. In addition, the processor 10 controls the communication circuit 11 to transmit the lot of the wafer to the extraction unit 562.

In the storage 53 (first storage), at least one piece of past time-series data of the physical quantity during the processing of the substrate is stored in association with the lot of the substrate. The extraction unit 562 refers to the storage 53 (first storage) and extracts the past time-series data (for example, at least one of the current value of the table rotating motor, the flow rate of water/or slurry, the polishing pressure, the rotation speed of the polishing table, and/or the rotation speed of the top ring, and the like) of the physical quantity that corresponds to the lot of the substrate to be processed. The extracted past time-series data (past time-series data of the sensor value) of the physical quantity is transmitted to the maintenance necessity decision unit 663.

The maintenance necessity decision unit 663 compares the time-series data of the physical quantity at the time of the occurrence of the abnormality detected by the sensor, in this case, the table motor current detection unit 45 and/or the sensors 21 to 24 as an example) with the past time-series data of the physical quantity extracted by the extraction unit 562 to judge whether maintenance needs to be performed.

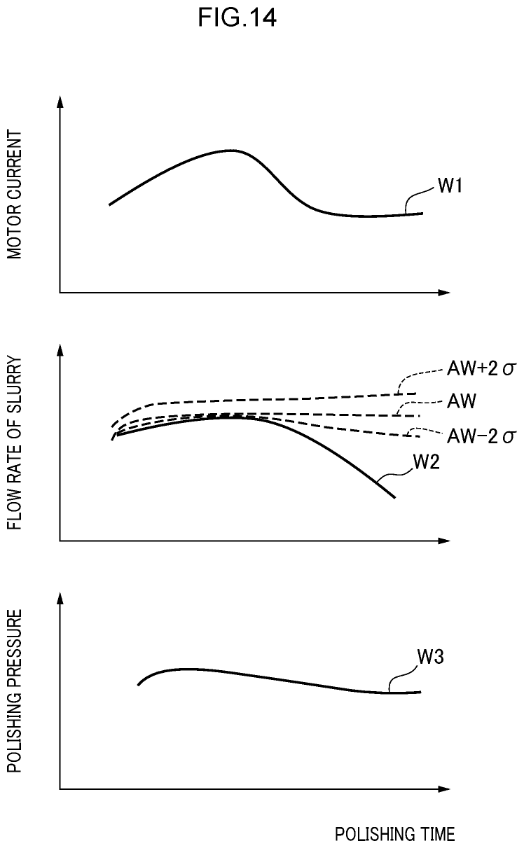

FIG. 14 is a diagram for explaining a comparison process in the maintenance necessity decision unit 663. FIG. 14 illustrates a time-series change Wi in the current of the motor, a time-series change W2 in the flow rate of the slurry, and a time-series change W3 in the polishing pressure as the time-series data of the physical quantity at the time of the occurrence of the abnormality. On the other hand, the average AW, the average AW−2σ (σ is a standard deviation), and the average AW+2σ of the past time-series data of the flow rate of the slurry are illustrated, and it is illustrated that the time-series change W2 in the flow rate of the slurry deviates from a preset range (for example, AW−2σ to AW+2σ) based on the average AW of the past time-series data of the flow rate of the slurry. As described above, when the time-series data of the physical quantity at the time of the occurrence of the abnormality deviates (or statistically dominantly deviates) from the preset range based on the past time-series data of the same physical quantity, the maintenance necessity decision unit 663 judges that maintenance needs to be performed. In this case, the maintenance necessity decision unit 663 judges that an abnormality is present in the flow rate of the slurry and no abnormality is present in the current of the motor and the polishing pressure. The maintenance necessity decision unit 663 controls the communication circuit 62 to transmit, to the analysis server 7, information, which has been judged, indicating whether maintenance needs to be performed and the time-series data (time-series data of the sensor value at the time of the occurrence of the abnormality) of the physical quantity at the time of the occurrence of the abnormality. Note that the maintenance necessity decision unit 663 detects one abnormal parameter or a plurality of abnormal parameters among the plurality of compared parameters (time-series data of the physical quantities).

As described above with reference to FIG. 7, the storage 73 (second storage) of the analysis server 7 stores a combination of the presence or absence of an abnormality in at least one or more physical quantities and a factor of the abnormality and/or a solution to the abnormality in association with each other. When the maintenance necessity decision unit 663 judges that the maintenance needs to be performed, the factor analysis unit 763 of the analysis server 7 refers to the storage 73 (second storage) and outputs the factor of the abnormality and/or the solution to the abnormality according to the combination of the presence or absence of the abnormality in the one or more physical quantities. The factor analysis unit 763 of the analysis server 7 controls the communication circuit 72 to transmit, to the terminal device 9, the time-series data (time-series data of the sensor value at the time of the occurrence of the abnormality) of the physical quantity at the time of the occurrence of the abnormality and the factor of the abnormality and/or the solution to the abnormality. Then, the terminal device 9 that has received these pieces of information displays these pieces of information. As a result, maintenance personnel of the substrate processing apparatus can immediately grasp the factor of the abnormality and/or the solution to the abnormality by confirming these pieces of information using the terminal device 9, and thus can quickly solve the abnormality of the polishing apparatus by, for example, going to the local polishing apparatus.

As described above, the substrate processing system according to the present embodiment includes a sensor (in this case, the table motor current detection unit 45 as an example) installed in a substrate processing apparatus and configured to detect a target physical quantity during processing of a target substrate, and a prediction unit configured to output a polishing end point timing, which is timing of ending polishing, by inputting, to a learned machine learning model, time-series data of the physical quantity (in this case, the current value of the table rotating motor as an example) detected by the sensor (in this case, the table motor current detection unit 45 as an example) or time-series data obtained by differentiating the time-series data of the physical quantity (in this case, the current value of the table rotating motor as an example) with respect to time. In this case, the machine learning model is obtained by machine learning using, as the learning data set, past time-series data of the physical quantity (in this case, the current value of the table rotating motor as an example) or the time-series data obtained by differentiating the past time-series data of the physical quantity (in this case, the current value of the table rotating motor as an example) with respect to time as input and the past polishing end point timing as output.

According to this configuration, since the polishing end point timing can be automatically predicted, it is possible to reduce the time and cost required for predicting the polishing end point timing, and save labor, energy, and/or cost. In addition, conventionally, there has been a problem that a plurality of minimum points (or maximum points) is generated when time-series data obtained by differentiating time-series data of the current value of a table rotating motor with respect to time is used, and it is not possible to determine in real time which minimum point (or maximum point) time is a polishing end point timing. On the other hand, since the machine learning model after learning is learned using the learning data set in which past time-series data of the physical quantity or the time-series data obtained by differentiating the past time-series data of the physical quantity with respect to time is used as input and the past polishing end point timing is used as output, it is possible to improve the possibility that the correct polishing end point timing can be output even when time-series data of an unknown physical quantity or time-series data obtained by differentiating the time-series data of the physical quantity with respect to time is input.

<Second Embodiment>

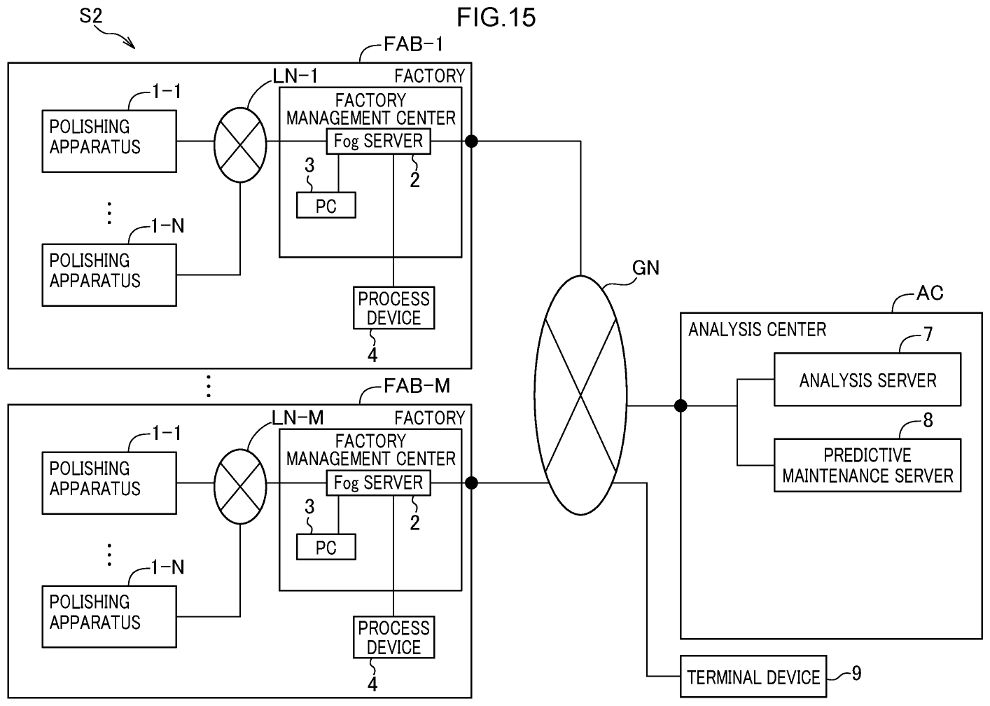

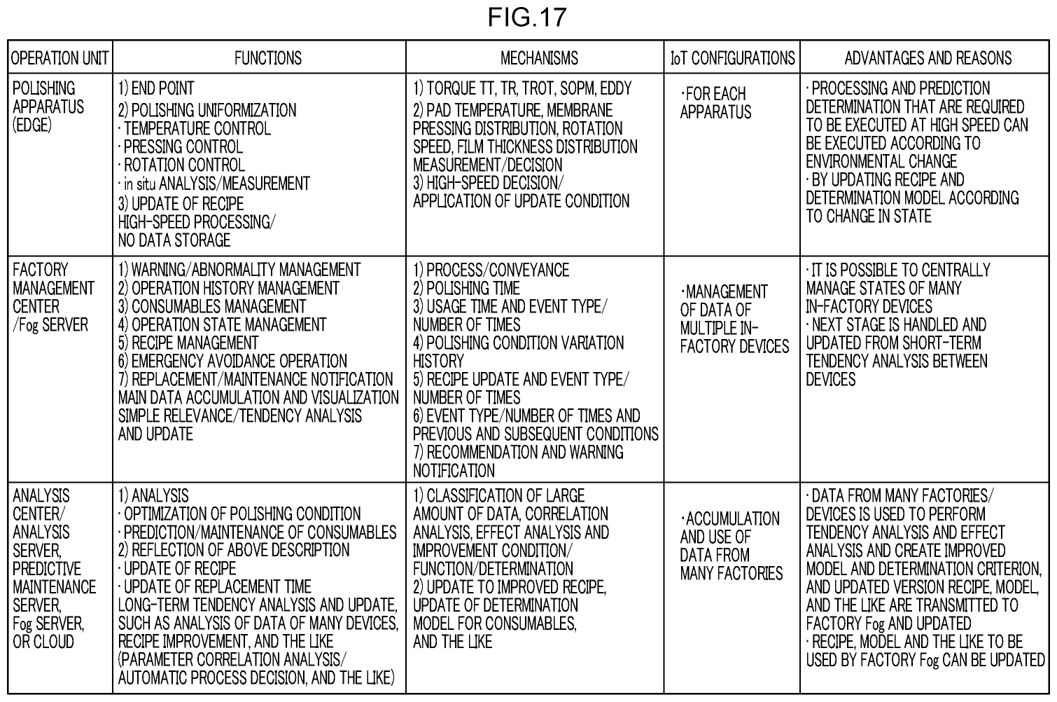

Next, a second embodiment will be described. FIG. 15 is a diagram illustrating a schematic configuration of a substrate processing system according to a second embodiment. As illustrated in FIG. 15, in the substrate processing system S2 according to the second embodiment, a Fog server 2 is provided in a factory management center, as compared with the substrate processing system S1 according to the first embodiment. The Fog server 2 acquires information from each server of analysis data in order to implement functions of the Fog server that are illustrated in FIG. 17 described later.

<Third Embodiment>

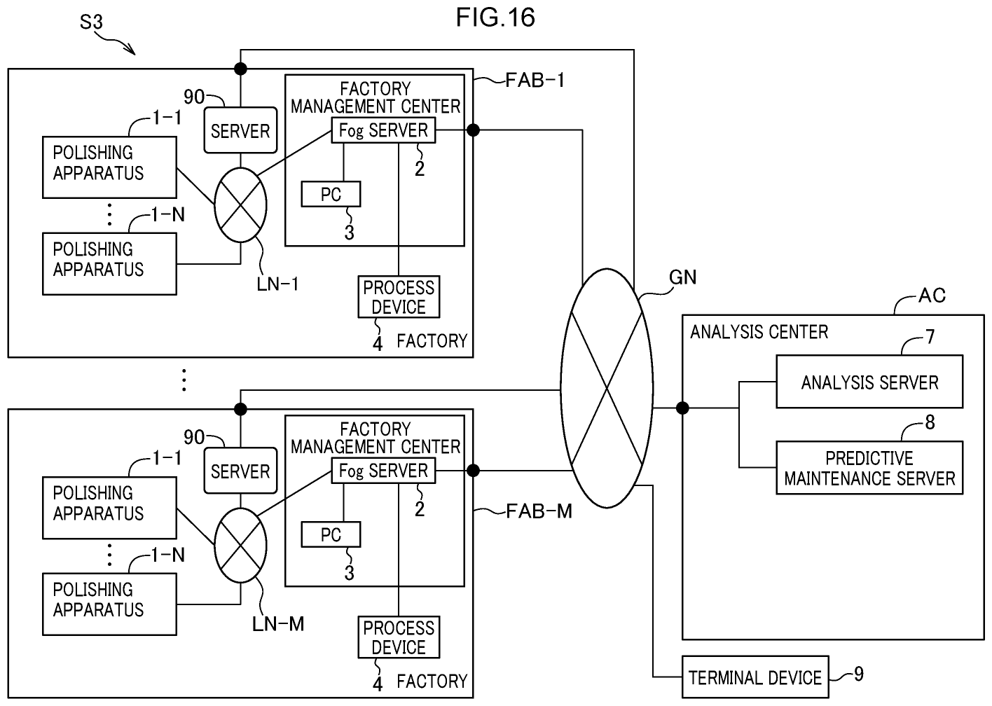

FIG. 16 is a diagram illustrating a schematic configuration of a substrate processing system according to a third embodiment. As illustrated in FIG. 16, in the substrate processing system S3 according to the third embodiment, a server 90 is provided for each factory, as compared with the substrate processing system S2 according to the second embodiment. The server 90 functions as a gateway server. The server 90 is connected to the global network GN and is connected to a corresponding local area network LN-i (i is an integer from 1 to M). The server 90 is used for maintenance in each factory.

FIG. 17 is a table summarizing functions, mechanisms, IoT configurations, advantages, and reasons in each operation unit in the substrate processing systems according to the first to third embodiments. The polishing apparatus 1 (processor provided therein) is a processor installed at an edge in so-called edge computing, that is, a controller in the apparatus, a gateway in the vicinity of the apparatus, or the like, and may have the following functions. (1) The processor 10 of the polishing apparatus 1 detects the polishing end point timing using the current value (torque TT) of the table rotating motor that indicates the measured torque of the table, the rotating motor current value (torque) (TR) of the top ring, a current value (torque TROT) of a top ring swing rotating motor, an output signal (SOPM) of the optical film thickness sensor, or an output signal of the eddy current film thickness sensor.

(2) The processor 10 of the polishing apparatus 1 performs polishing uniformization, pad temperature control, membrane pressing control, or control of the rotation of the table or the top ring by using a measured pad temperature, a membrane pressing distribution, a rotation speed, or a film thickness distribution.

(3) The processor 10 of the polishing apparatus 1 updates the recipe (high-speed processing/no data storage) by performing high-speed decision/applying an update condition.

The processor of the Fog server 2 in the factory management center has mechanisms of (1) process/conveyance, (2) polishing time, (3) usage time and event type/number of times, (4) polishing condition variation history, (5) recipe update and event type/number of times, (6) event type/number of times and previous and subsequent conditions, and (7) recommendation and warning notification.

As a result, the processor of the Fog server 2 in the factory management center has functions of (1) warning/abnormality management, (2) operation history management, (3) consumables management, (4) operation state management, (5) recipe management, (6) emergency avoidance operation, and (7) replacement/maintenance notification, main data accumulation and visualization, simple relevance/tendency analysis, and update.

In this manner, the Fog server 2 manages data of a plurality of in-factory devices. As a result, it is possible to centrally manage states of a large number of devices in the factory, and it is possible to handle the next stage and perform an update from short-term tendency analysis between devices.

The processor 76 of the analysis server 7 of the analysis center AC analyzes (or analyzes) a factor at the time of the occurrence of an abnormality using classification of a large amount of data, correlation analysis, effect analysis and an improvement condition, a set function, and the like. The processor 86 of the predictive maintenance server 8 of the analysis center AC determines a processing condition (improved recipe) in which the polishing condition is optimized, and performs control to update the processing condition (recipe) with the determined processing condition (improved recipe).

In addition, the processor 86 of the predictive maintenance server 8 of the analysis center AC predicts the replacement time of consumables of the polishing apparatus 1 using a determination model for the consumables of the polishing apparatus 1, and updates the replacement time of the consumables each time the determination model for the consumables is updated or the like. As a result, since the replacement time of the consumables of the polishing apparatus 1 can be appropriately predicted, the polishing apparatus 1 can be maintained.

The processor 76 of the analysis server 7 of the analysis center AC or the processor 86 of the predictive maintenance server 8 may perform long-term tendency analysis and an update, such as analysis of data of a large number of devices and recipe improvement (parameter correlation analysis/automatic process decision and the like).

At the time of the execution, the analysis server 7 and the predictive maintenance server 8 of the analysis center AC accumulate and use data from a large number of factories. As a result, tendency analysis or effect analysis of processing conditions (polishing conditions, recipe) is performed by using data from a large number of factories/devices. In addition, an improved model or a determination criterion is created by using data from a large number of factories/devices, and these updated items (updated versions) are sent to the Fog server 2 of the factory center, so that the Fog server 2 can execute the updated items. That is, the recipe, the model, and the like to be used by the Fog server 2 of the factory center can be updated. In addition, the processor of the analysis server 7 of the analysis center AC may analyze a gradual temporal tendency (for example, per month or day) at the time of performing end point processing or the like by the edge, and send the improved recipe to the processor (or controller) of the edge to update the recipe of the target polishing apparatus. For example, waveform data (for example, waveform data of the torque TT) used to detect the end point of the polishing apparatus may be accumulated in a data center (or the analysis center), the removal of waveform noise of the corresponding polishing apparatus may be analyzed by the processor of the analysis server 7 of the analysis center AC, and the processor of the analysis server 7 of the AC may generate and use a learned model (tuned neural network) for preprocessing that performs noise separation. An update recipe can be sent from the analysis center AC to the edge processor or controller, the edge processor can update the recipe, and the learning model for preprocessing of noise removal can be used. These recipes can be automatically updated by network communication. In addition, when communication cannot be performed, it is also possible to manually perform an update at the site.

Note that the processing in the analysis center AC may be executed in a cloud.

When high-speed processing is required on the edge side (for example, the polishing apparatus 1) (for example, in a case where the functions of the edge in FIG. 16 are implemented), processing is performed by the edge computing. The controller (or processor) in the polishing apparatus 1 or the server 90 on the gateway side executes the processing, for example, in a case where processing of 100 ms or less is required, for example, in a case where it is necessary to cope with a temporal change such as a case where end point prediction (waveform prediction) is performed online.

Since the processing of the functions that is executed by the Fog server illustrated in FIG. 16 and the processing of each server of the analysis center are management processing, the processing does not need to be performed so quickly, and thus may be executed by the Fog server or each server of the analysis center.

<Description of Artificial Intelligence (AI)>

In the learned (tuned) machine learning model, the input is the time-series data of the motor current from the start of the polishing to the prediction time point, and the output is the correct prediction probability for each candidate value of the polishing end point timing, but the machine learning model is not limited to the above configuration.

In addition to the time-series data of the motor current from the start of the polishing to the prediction time point, the input of the machine learning model may be at least one of sensor outputs such as the current value of the table rotating motor from the start of the polishing to the prediction time point, the current value of the top ring rotating motor, the torque of the table, the intensity of light scattered when the light is applied to the substrate, the intensity of a magnetic field line due to an eddy current generated by applying the magnetic field line to the substrate, and physical quantities indicating the state of the polishing apparatus, such as other parameters (pad temperature, membrane pressing, the rotation speed of the polishing table or the polishing table, and the amount of slurry). As a result, the uniformity of the polished surface is improved, and the accuracy of the polishing end point timing is further improved.

Alternatively, instead of the time-series data of the motor current from the start of the polishing to the prediction time point, the input of the machine learning model may be at least one of sensor outputs such as the current value of the table rotating motor from the start of the polishing to the prediction time point, the current value of the top ring rotating motor, the torque of the table, the intensity of light scattered when the light is applied to the substrate, the intensity of a magnetic field line due to an eddy current generated by applying the magnetic field line to the substrate, and physical quantities indicating the state of the polishing apparatus, such as other parameters (pad temperature, membrane pressing value, rotation speeds of the table/top ring, flow rate of slurry, and the like).

Note that the machine learning model may be implemented as a computer program product. For example, the computer program product controls processing of a substrate, and is embodied in a non-transitory computer recording medium, and includes an instruction to cause the processor to execute at least one part of the above-described processing.

Furthermore, the output of the machine learning model may be a program for outputting a control parameter, or may be a parameter after correction.

<Selection of Learning Data Set>

In the above embodiment, the normal data set is used as the result of detecting the end point as the learning data set, but the learning data set is not limited thereto. The result of detecting the end point may be an abnormal data set or a mixed data set (in which normal data is, for example, 80% or more of the mixed data set) in which normal data and abnormal data are mixed.

As the machine learning, automatic learning may be performed using a neural network (for example, deep learning), reinforcement learning, a support vector machine, or the like. Furthermore, the machine learning may be enabled by quantum computing.

<First Example of Neural Network>

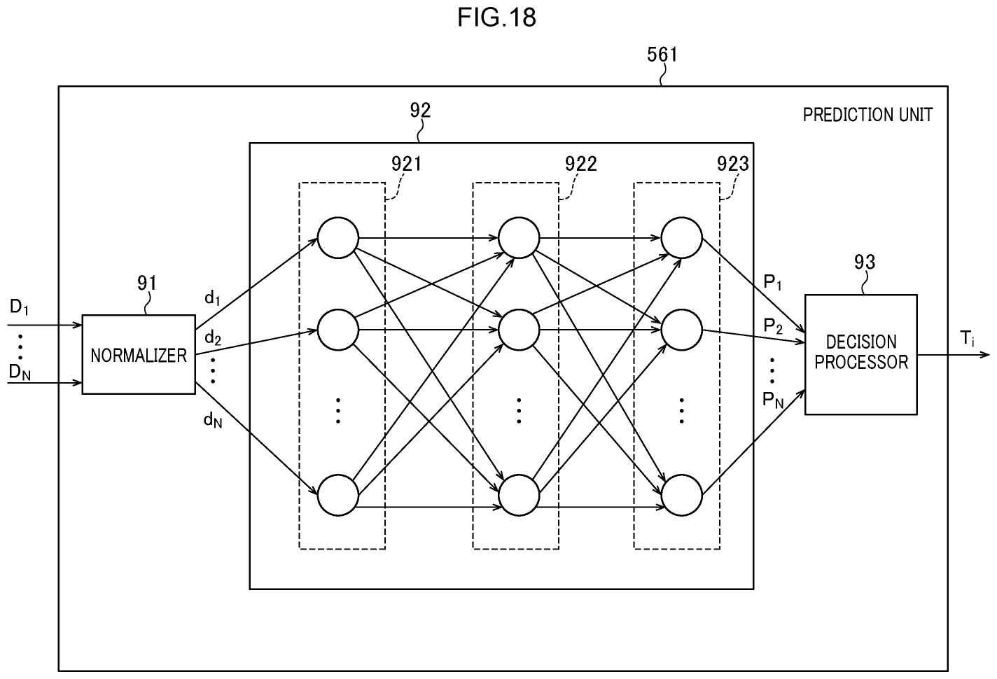

In this case, an example achieved by a neural network as machine learning will be described with reference to FIG. 18. FIG. 18 is an example of a neural network according to each embodiment. As illustrated in FIG. 18, the prediction unit 561 includes a normalizer 91, a neural network 92, and a decision processor 93. The prediction unit 561 normalizes physical quantity time-series data (for example, time-series data of the motor current) Di to DN indicating the state of the above-described polishing apparatus by means of the normalizer 91. The normalized data d₁ to d_{N} is input to the neural network 92, and the neural network 92 generates correct prediction probabilities P₁ to P_{N} for each of a plurality of candidate values of the polishing end point timing (N is a positive integer). When a probability exceeding a threshold is present among the plurality of generated correct prediction probabilities, the decision processor 93 outputs, as the polishing end point timing, a candidate value Tᵢ of the polishing end point timing that corresponds to the correct prediction probability Pi exceeding the threshold (i is an index).

In this case, the neural network 102 includes a plurality of input nodes that receive the data d₁ to d_{N} obtained by normalizing the physical quantity time-series data (for example, time-series data of the motor current) D₁ to D_{N} indicating the state of the polishing apparatus described above, a plurality of output nodes that are assigned for each polishing end point timing and output correct prediction probabilities, and a plurality of hidden nodes whose inputs are connected to outputs of at least one or more of the input nodes and whose outputs are connected to inputs of at least one or more of the output nodes.

A part of or the entire the neural network 102 may be enabled by software, or a part of or the entire neural network 102 may be enabled by hardware. In a case where the neural network 102 is enabled by hardware, for example, as illustrated in FIG. 18, the neural network 102 may include a first filter 921 constituting an input node, a second filter 922 constituting a hidden node, and a third filter 923 constituting an output node.

<Fourth Embodiment>

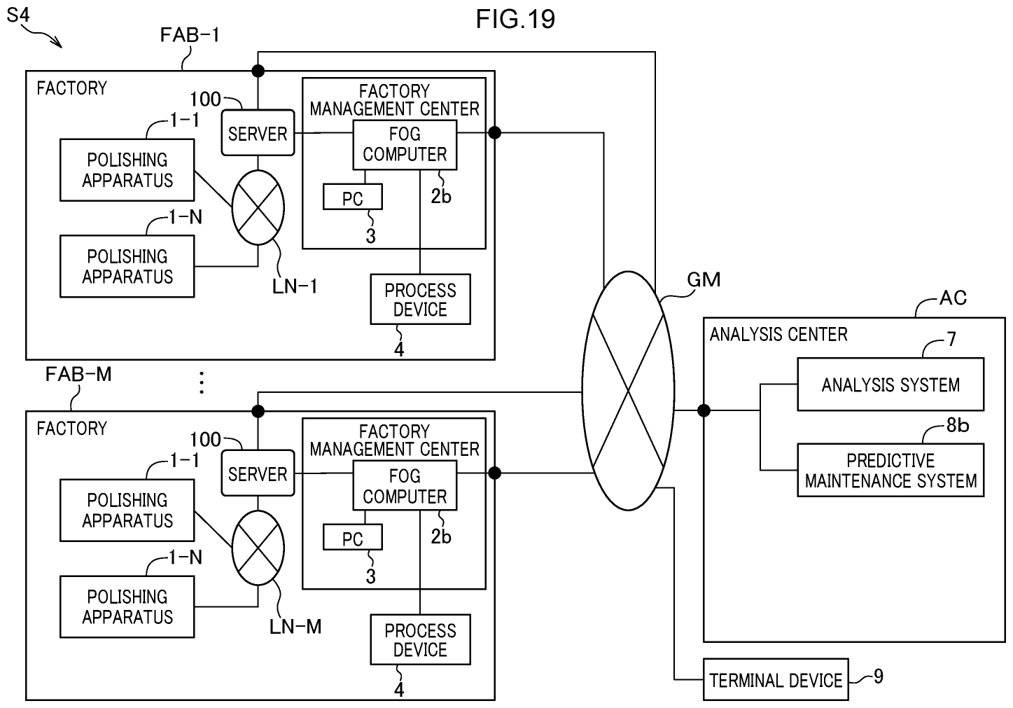

Next, a fourth embodiment will be described. FIG. 19 is a diagram illustrating a schematic configuration of a substrate processing system according to a fourth embodiment. The Fog server 2 is connected to the local area network LN-i in the substrate processing system according to the third embodiment of FIG. 16, whereas a fog computer 2b is connected to a server 100. This feature is different. As a result, only data processed by the server 100 which is an example of an information processing apparatus is transmitted to the fog computer 2b. Note that, as compared with FIG. 16, the predictive maintenance system 8 is replaced with a predictive maintenance system 8b, and the terminal device 9 is removed.

<Connection Form and Functional requirements>

(1) The server 100 is installed in each factory. The server 100 can collect and analyze operation data of the plurality of substrate processing apparatuses (in this case, polishing apparatuses, which are also referred to as semiconductor manufacturing apparatuses as an example). For example, it is possible to analyze a difference in polishing condition between the apparatuses. It is possible to generate an update parameter according to the difference, transmit update data, and the like. In addition, the server 100 can be connected to the fog computer (for example, a fog server) 2b for factory management and a PC 3 for an administrator. A factory manager can access the server 100 from the PC 3 to analyze data and generate the update parameter. In addition, the data can be downloaded from the server 100 to the fog computer b or the PC 3 for the administrator, and the factory manager can analyze the data and generate the update parameter in the fog computer 2b or the PC 3.

(2) Furthermore, a service provider can connect to the server 100 from the outside of the factory or from a place (such as a vendor room) outside a building in which the apparatuses of the factory are installed. The service provider can analyze data of the plurality of substrate processing apparatuses (also referred to as semiconductor manufacturing apparatuses, for example, polishing apparatuses). In addition, for example, it is possible to change polishing parameters of the polishing apparatuses, analyze a correlation of polishing results, change polishing uniformity, generate an update parameter for maintaining uniformity, transmit the update parameter to the corresponding apparatuses, update the parameters, and the like.

(3) Each of the substrate processing apparatuses (also referred to as semiconductor manufacturing apparatuses) is a polishing apparatus (also referred to as a CMP apparatus), a plating apparatus, a bevel polishing apparatus, an inspection apparatus, a package substrate polishing apparatus, an exposure apparatus, an etching apparatus, a polishing apparatus, a cleaning apparatus, a film forming apparatus, or the like. In a case where data of various types of apparatuses is used, it is possible to perform data analysis by monitoring a history of an apparatus row to be used before and after a process step and a variation in a parameter, and to perform abnormality detection and conditioning, create a consumable replacement schedule, and the like.

<Outline of Functions of Server 100>

The server 100 collects data, such as the polishing parameters and/or sensor detection values, from each of the polishing apparatuses.

The server 100 adjusts the polishing parameters of each of the polishing apparatuses to minimize a difference in polishing status between the polishing apparatuses.

The server 100 analyzes a trouble factor using the sensor detection values. This makes it possible to perform analysis early and prevents a trouble in advance.

<Functions and Processing Items of Server 100>

1. Data Collected by the Processor of the Server 100 from the Polishing Apparatus 1

The collected data is, for example, at least one of the following data pieces. Usage time of consumables (retainer ring, pad, membrane, dresser tool, brush, frame), the number of processed substrates/units, torque fluctuation during polishing (motor current), a result of measurement of a film thickness by an In-Line Thickness Metrology (ITM) built in a polishing apparatus, End Point Detection (EPD) data, environment data (pad temperature, polishing unit temperature/humidity, slurry temperature), wafer conveyance data (position, torque, speed, and acceleration), and the like.

2. Reduction (Desirably, Minimization) in a Difference Between Polishing Apparatuses

Among the torque data (for example, the motor current for rotation of the polishing table) and other parameters, the processor of the server 100 extracts (1) a parameter group correlated with a “polishing condition” (for example, the polishing amount or the like) (that is, a parameter group relevant to the polishing condition), (2) a parameter group correlated with a “polishing table condition (state)” (that is, a parameter group relevant to the polishing table condition (state)), or (3) a parameter group correlated with “dressing uniformity” (that is, a parameter group relevant to dressing uniformity).

In this case, the extraction method may extract the correlated parameters by obtaining eigen values in principal component analysis.

Then, the processor of the server 100 may adjust parameters of the parameter group relevant to the polishing condition such that a difference in “polishing condition” (for example, polishing amount or the like) between the polishing apparatuses is reduced.

Additionally/alternatively, the processor of the server 100 may adjust parameters of the parameter group relevant to the polishing table condition (state) such that a difference in “polishing table condition (state)” between the polishing apparatuses is reduced.

Additionally/alternatively, the processor of the server 100 may adjust parameters of the parameter group relevant to the polishing table condition (state) such that a difference in “dressing uniformity” between the polishing apparatuses is reduced.

Even in a case of a parameter having a high correlation at an initial stage, the correlation varies with the lapse of time, and thus, it is necessary to monitor the correlation over time. Therefore, as an example, the processor of the server 100 may calculate, for each polishing apparatus, cumulative contribution data, which is a cumulative value of a correlation value (for example, a correlation coefficient) indicating a correlation of a correlated parameter, and monitor a variation in the cumulative contribution data between the polishing apparatuses. Then, in a case where the variation deviates from a predetermined range, the processor of the server 100 may determine that a sign of an abnormality is present and update a parameter (for example, a parameter having a high correlation value). In this case, as the correlation value indicating the correlation, a parameter having a strong correlation in which the correlation value is equal to or higher than a threshold (for example, 0.5) may be selected.

The processor of the server 100 monitors the correlation value of the correlated parameter over time and updates the parameter (for example, a parameter having a high correlation value) when the correlation coefficient deviates from a predicted range.

Furthermore, for example, in a case where a parameter in which the original correlation value is lower than the threshold but the correlation value is higher than the threshold newly appears, the processor of the server 100 may update the new parameter.

3. Early Analysis of Trouble Factors

The processor of the server 100 may prioritize a parameter having a high correlation value and compare the parameters between the polishing apparatuses. Then, in a case where a variation (degree of deviation, for example, difference or the like) in a parameter having a high correlation value is out of a predicted range, the processor of the server 100 may detect that it is a trouble factor and update the parameter (for example, the parameter having a high correlation value).

4. Prevention of Trouble

In order to prevent a trouble in advance, the processor of the server 100 may output information prompting maintenance when a variation (for example, a degree of deviation, for example, a difference or the like) in a parameter having a high correlation value exceeds a threshold. For example, the processor of the server 100 may output that it is better to perform maintenance after X (X is a predetermined number) hours.

As a result, it is possible to monitor a sign of a failure based on a variation (for example, a degree of deviation) in a parameter having a high correlation value. In addition, it is possible to build a platform that efficiently collects, accumulates, visualizes, and analyzes operation data of the polishing apparatuses (CMP apparatuses). In addition, data of the plurality of substrate processing apparatuses (for example, polishing apparatuses) or semiconductor manufacturing apparatuses in the factory can be accumulated in the server 100.

<Usage Examples: Analysis of Trouble Factor and Prevention of Trouble>

The server 100 stores data of the plurality of polishing apparatuses to built-in or external storage and performs data analysis. This minimizes downtime due to a failure or replacement of a part. For this purpose, the server 100 analyzes data, for example, the usage time of consumables such as a pad, a retainer ring, a membrane, and a rotating part motor, the number of processed substrates, a consumption degree evaluation value, a change with time in a polishing time in end point detection, a change with time in polishing uniformity, and the like, and estimates, based on the data analysis, a predicted value of the replacement time of the consumables, a remaining usable time, a conditioning execution time, and the like.

Next, for example, the server 100 generates an update parameter for maintaining and stabilizing (correcting) polishing characteristics, estimates a predicted value of the replacement time of the consumables, a remaining usable time, and a conditioning execution time in a case where the update parameter is used, estimates a maintenance time in a case where the update parameter is used, and notifies the factory manager or the service provider of the estimated values. The values may be notified by e-mail or a message service, or may be notified by the PC 3 of the factory manager or an application installed in the terminal device 9 of the service provider.

Note that the above trouble factor analysis and prevention may be executed by an analysis system 7 and/or the predictive maintenance system 8b, instead of the server 100.

As described above, the substrate processing system according to the fourth embodiment includes the server 100 connected to the plurality of substrate processing apparatuses (for example, the polishing apparatuses 1) via a communication line, and the fog computer 2b or the terminal (for example, PC 3) connected to the server via a communication line. The server 100 collects data from the plurality of substrate processing apparatuses (for example, the polishing apparatuses 1), processes the collected data, and transmits a result of the processing to the fog computer 2b or the terminal (for example, PC 3). The fog computer 2b or the terminal (for example, PC 3) performs control so as to output the result of the processing upon receiving the result of the processing.

With this configuration, the fog computer or the terminal can output a result of processing data collected by the server from the plurality of polishing apparatuses 1.

The server 100 includes: means for extracting, from the collected data, parameters having a correlation of a standard or higher with a substrate processing condition (for example, a polishing condition), a substrate processing table state (for example, a polishing table state), and/or dressing uniformity; and means for comparing the extracted parameters between the substrate processing apparatuses (for example, polishing apparatuses) and updating at least one parameter of the data according to a result of the comparison.

As a result, since substrate processing conditions (for example, polishing conditions), substrate processing table states (for example, polishing table states), and/or dressing uniformity can be brought close to each other, it is possible to reduce a variation in the substrate processing (for example, polishing) between the substrate processing apparatuses (for example, polishing apparatuses).

Note that at least a part of the substrate processing systems S1 to S4 described in the above-described embodiments may be configured by hardware or software. In a case where it is configured by the hardware, a program for implementing at least some of the functions of the substrate processing systems S1 to S3 may be stored in a recording medium such as a flexible disk or a CD-ROM, and may be read and executed by a computer. The recording medium is not limited to a removable recording medium such as a magnetic disk or an optical disk, and may be a fixed recording medium such as a hard disk device or a memory.

In addition, a program for implementing at least some of the functions of the substrate processing systems S1 to S4 may be distributed via a communication line (including wireless communication) such as the Internet. Further, the program may be distributed via a wireless line or a wired line such as the Internet or stored in a recording medium in an encrypted, modulated, or compressed state.

In the invention of the method, all the processes (steps) may be enabled by automatic control by a computer. In addition, progress control between the processes may be manually performed while causing a computer to perform each process. Furthermore, at least some of all the steps may be manually performed.

As described above, the present invention is not limited to the above-described embodiments as it is, and can be embodied by modifying the components without departing from the gist of the present invention in the implementation stage. In addition, various inventions can be formed by appropriately combining a plurality of components disclosed in the above embodiments. For example, some components may be removed from all the components described in the embodiments. Furthermore, components in different embodiments may be appropriately combined.

### REFERENCE SIGNS LIST

1 Polishing apparatus
10 Processor
11 Communication circuit
2 Fog server
21 to 24 Sensor
30 Polishing table
30a Table shaft
32 Polishing pad
34 Top ring shaft
35 Top ring
38 Polishing liquid supply mechanism
4 Process device
40 Table rotating motor
41 Top ring rotating motor
45 Table motor current detection unit
5 Recipe server
51 Input interface
52 Communication circuit
53 Storage
54 Memory
55 Output interface
56 Processor
561 Prediction unit
562 Extraction unit
6 Alarm server
61 Input interface
62 Communication circuit
63 Storage
64 Memory
65 Output interface
66 Processor
661 Decision unit
662 Update control unit
663 Maintenance necessity decision unit
7 Analysis server
71 Input interface
72 Communication circuit
73 Storage
74 Memory
75 Output interface
76 Processor
761 Selection unit
762 Learning unit
763 Factor analysis unit
8 Predictive Maintenance Server
81 Input interface
82 Communication circuit
83 Storage
84 Memory
85 Output interface
86 Processor
861 Determination unit
9 Terminal device
90 Server
91 Normalizer
92 Neural network
93 Decision processor
100 Server

1. A substrate processing system comprising:
a sensor installed in a substrate processing apparatus and configured to detect a target physical quantity during processing of a target substrate; and
a prediction unit configured to output a polishing end point timing, which is timing of ending polishing, by inputting, to a learned machine learning model, time-series data of the physical quantity detected by the sensor or time-series data obtained by differentiating the time-series data of the physical quantity with respect to time, wherein
the machine learning model is obtained by machine learning using, as a learning data set, past time-series data of the physical quantity or time-series data obtained by differentiating the past time-series data of the physical quantity with respect to time as input and the past polishing end point timing as output.

2. The substrate processing system according to claim 1, further comprising:
a decision unit configured to compare the time-series data of the physical quantity detected by the sensor with the past time-series data and judge whether an abnormality is present in a time-series change in the physical quantity;
a determination unit configured to determine a processing condition again when the decision unit judges that the abnormality is present; and
an update control unit configured to perform control to perform an update with the processing condition determined by the determination unit.

3. The substrate processing system according to claim 1, wherein
the target physical quantity is a current value of a table rotating motor of the substrate processing apparatus, a current value of a top ring rotating motor of the substrate processing apparatus, or torque of a table of the substrate processing apparatus, and
the substrate processing system further comprises:
a selection unit configured to select time-series data of a current value detected by the sensor based on time-series data obtained by differentiating the time-series data of the current value with respect to time; and
a learning unit configured to generate the learned machine learning model by performing machine learning using, as the learning data set, the time-series data of the current value selected by the selection unit as input and the polishing end point timing as output.

4. The substrate processing system according to claim 3, wherein when a minimum point or a maximum point that satisfies a setting criterion is not detected in the time-series data differentiated with respect to time, the selection unit selects the time-series data of the current value by excluding the time-series data of the current value before the differentiation.

5. A substrate processing system comprising:
a sensor installed in a substrate processing apparatus and configured to detect a target physical quantity during processing of a target substrate;
storage in which at least one piece of past time-series data of the physical quantity during the processing of the substrate is stored in association with a lot of substrate;
an extraction unit configured to refer to the storage and extract the past time-series data of the physical quantity that corresponds to the lot of the target substrate to be processed; and
a decision unit configured to compare the time-series data of the physical quantity detected by the sensor with the past time-series data extracted by the extraction unit and judge whether an abnormality is present in a time-series change in the physical quantity.

6. The substrate processing system according to claim 5, further comprising:
a determination unit configured to determine a processing condition again when the decision unit judges that the abnormality is present; and
an update control unit configured to perform control to perform an update with the processing condition determined by the determination unit.

7. A substrate processing system comprising:
at least one sensor installed in a substrate processing apparatus and configured to detect a target physical quantity during processing of a target substrate;
first storage in which at least one piece of past time-series data of the physical quantity during the processing of the substrate is stored in association with a lot of the substrate;
an extraction unit configured to refer to the first storage and extract the past time-series data of the physical quantity that corresponds to the lot of the target substrate to be processed; and
a maintenance necessity decision unit configured to compare the time-series data of the physical quantity detected by the sensor at the time of occurrence of an abnormality with the past time-series data of the physical quantity extracted by the extraction unit to judge whether maintenance needs to be performed;
second storage in which a combination of presence or absence of an abnormality in at least one or more physical quantities and a factor of the abnormality and/or a solution to the abnormality are stored in association with each other; and
a factor analysis unit configured to refer to the second storage and output the factor of the abnormality and/or the solution to the abnormality according to the combination of presence or absence of the abnormality in the one or more physical quantities when the maintenance necessity decision unit judges that the maintenance needs to be performed.

8. A substrate processing system comprising:
an information processing apparatus connected to a plurality of substrate processing apparatuses via a communication line; and
a fog computer or a terminal connected to the information processing apparatus via a communication line, wherein
the information processing apparatus collects data from the plurality of substrate processing apparatuses, processes the collected data, and transmits a result of the processing to the fog computer or the terminal, and
the fog computer or the terminal performs control to output the result of the processing upon receiving the result of the processing.

9. The substrate processing system according to claim 8, wherein,
the information processing apparatus includes:
means for extracting, from the collected data, a parameter having a correlation of a standard or higher with a substrate processing condition, a substrate processing table state, and/or dressing uniformity; and
means for comparing the extracted parameters between the substrate processing apparatuses and updating at least one parameter of the data according to a result of the comparison.
